(19) United States
(12) Patent Application Publication
(10) Pub. No.: US 2026/0090211 A1
(43) Pub. Date: Mar. 26, 2026

(54) DISPLAY DEVICE, ELECTRONIC DEVICE, AND METHOD FOR FABRICATION OF DISPLAY DEVICE

(71) Applicant: Samsung Display Co., Ltd., Yongin-si (KR)

(72) Inventors: Ji Yoon KIM, Yongin-si (KR); Hyeon Sik KIM, Yongin-si (KR); Dong Hee LEE, Yongin-si (KR); Hee Woon IM, Yongin-si (KR)

(21) Appl. No.: 19/235,273

(22) Filed: Jun. 11, 2025

(30) Foreign Application Priority Data
Sep. 20, 2024 (KR) 10-2024-0127338

(51) Int. Cl. H10K 59/122; H10K 59/12; H10K 59/80

(52) U.S. Cl. CPC H10K 59/122; H10K 59/1201; H10K 59/80515; H10K 59/80521; H10K 59/873

(57) ABSTRACT

There is provided a display device. The display device includes a substrate including an emission area and a non-emission area; a passivation layer on the substrate; a first anode electrode on the passivation layer; a pixel defining layer on the first anode electrode to overlap the non-emission area and defining a first opening; a bank structure on the pixel defining layer and defining a second opening; a first cathode electrode on the first anode electrode and in contact with the bank structure; and a first element inorganic layer on the first cathode electrode, wherein the bank structure includes a first bank layer and a second bank layer having a tip protruding toward the first opening beyond a side surface of the first bank layer, and the tip of the second bank layer is tilted toward the substrate as it extends toward the first opening.

### CROSS-REFERENCE TO RELATED APPLICATION

The present application claims priority to and the benefit of Korean Patent Application No. 10-2024-0127338, filed on Sep. 20, 2024, in the Korean Intellectual Property Office, the entire content of which is incorporated herein by reference.

### BACKGROUND

### 1. Field One or more embodiments of the present disclosure relate to a display device, a method for fabrication thereof, and an electronic device including the display device.

### 2. Description of the Related Art

With the advancement of the information-oriented society, increasing demands are placed on display devices for displaying images in one or more suitable ways. For example, display devices are employed in one or more suitable electronic devices such as smartphones, digital cameras, laptop computers, navigation devices, and/or smart televisions. The display device may be a flat panel display device such as a liquid crystal display device, a field emission display device, and/or an organic light emitting display device. Among flat panel display devices, in a light emitting display device, each of pixels of a display panel includes a light emitting element capable of emitting light by itself, allowing an image to be displayed without a backlight unit providing light to the display panel.

Recently, display devices have been employed in glass-type (kind) devices for providing virtual reality and/or augmented reality. To be used in glass-type devices, the display device needs to be implemented in a very small size, e.g., 2 inches or less, and/or needs to have a high pixel pitch to provide high resolution. For example, the display device may have a high pixel pitch of 1,000 pixels per inch (PPI) or more.

However, if (e.g., when) the display device is implemented in a small size and/or has a high pixel pitch, it is difficult to implement light emitting elements separately for each emission area by a mask process because the area of the emission area where the light emitting element is arranged is reduced.

### SUMMARY

One or more aspects of embodiments of the present disclosure are directed toward a display device in which a light emitting layer or a cathode electrode is formed separately for each emission area without a separate fine metal mask, and a method for fabrication thereof.

One or more aspects of embodiments of the present disclosure are directed toward a display device capable of solving a reliability defect due to moisture permeation, and a method for fabrication thereof.

One or more aspects of embodiments of the present disclosure are directed toward an electronic device with improved performance by including the display device.

However, aspects of the present disclosure are not restricted to those set forth herein. The above and other aspects of the present disclosure will become more apparent to one of ordinary skill in the art to which the present disclosure pertains by referencing the detailed description of the present disclosure provided herein or learning by practice of the presented embodiments of the disclosure.

According to one or more embodiments of the disclosure, a display device includes a substrate including an emission area and a non-emission area; a passivation layer on (e.g., positioned on) the substrate; a first anode electrode on (e.g., positioned on) the passivation layer; a pixel defining layer on (e.g., positioned on) the first anode electrode to overlap the non-emission area and defining a first opening; a bank structure on (e.g., positioned on) the pixel defining layer and defining a second opening; a first cathode electrode on (e.g., positioned on) the first anode electrode and in contact with the bank structure; and a first element inorganic layer on (e.g., positioned on) the first cathode electrode, wherein the bank structure includes a first bank layer and a second bank layer having a tip protruding toward the first opening beyond a side surface of the first bank layer, and the tip of the second bank layer is tilted toward the substrate as it goes (e.g., extends) toward the first opening.

In one or more embodiments, the passivation layer may include: a first passivation layer; and a second passivation layer on (e.g., positioned on) the first passivation layer and overlapping the non-emission area, and the second passivation layer includes: a first surface adjacent to (e.g., facing the first passivation layer; a second surface opposite to (e.g., facing) the first surface; and a side surface connecting the first surface and the second surface, wherein a width of the first surface is greater than a width of the second surface, and the side surface of the second passivation layer is an inclined surface.

In one or more embodiments, the first passivation layer and the side surface of the second passivation layer may form a first inclination angle.

In one or more embodiments, the first inclination angle may be equal to or greater than about 20 degrees and equal to or less than about 40 degrees, i.e., in a range of about 20 degrees to about 40 degrees.

In one or more embodiments, the tip of the second bank layer may overlap the side surface of the second passivation layer in a direction normal (e.g., perpendicular) to the substrate.

In one or more embodiments, the tip of the second bank layer may be tilted in a direction parallel to (e.g., substantially parallel to) the side surface of the second passivation layer.

In one or more embodiments, the side surface of the first bank layer and the tip of the second bank layer may form a second inclination angle, and the second inclination angle is equal to or greater than about 20 degrees and equal to or less than about 40 degrees, i.e., in a range of about 20 degrees to about 40 degrees. A width of the tip of the second bank layer in a direction parallel to the substrate may be equal to or greater than about 500 nanometers and equal to or less than 1000 nanometers, i.e., in a range of about 500 nanometers to about 1000 nanometers.

In one or more embodiments, the first anode electrode may be in contact with the side surface of the second passivation layer. And the display device may further include: a second anode electrode spaced and/or apart (e.g., spaced apart or separated) from the first anode electrode with the pixel defining layer interposed therebetween; and a second cathode electrode on (e.g., positioned on) the second anode electrode and in contact with the first bank layer, wherein the first cathode electrode and the second cathode electrode are electrically connected through the first bank layer.

In one or more embodiments, the display device may further include: a first light emitting layer on (e.g., positioned on) the first anode electrode and in contact with the first bank layer; and a second light emitting layer on (e.g., positioned on) the second anode electrode and in contact with the first bank layer, wherein the first light emitting layer and the second light emitting layer are spaced and/or apart (e.g., spaced apart or separated) from each other with the first bank layer interposed therebetween.

In one or more embodiments, the display device may further include a second element inorganic layer spaced and/or apart (e.g., spaced apart or separated) from the first element inorganic layer with the bank structure interposed therebetween, wherein the first element inorganic layer and the second element inorganic layer are spaced and/or apart (e.g., spaced apart or separated) from the second bank layer with a cavity (e.g., an undercut) interposed therebetween in a direction normal (e.g., perpendicular) to the substrate. The cavity (e.g., undercut) may overlap the tip of the second bank layer and the side surface of the second passivation layer in a direction normal (e.g., perpendicular) to the substrate.

In one or more embodiments, the pixel defining layer may include: a first pixel defining layer opposite to (e.g., facing) the emission area and having an inclined side surface; and a second pixel defining layer covering the first pixel defining layer with a substantially uniform thickness, wherein a side surface of the first pixel defining layer and the first anode electrode forms a third inclination angle.

In one or more embodiments, the third inclination angle may be equal to or greater than about 20 degrees and equal to or less than about 40 degrees, i.e., in a range of about 20 degrees to about 40 degrees, and the tip of the second bank layer overlaps the side surface of the first pixel defining layer in a direction normal (e.g., perpendicular) to the substrate.

According to one or more embodiments of the disclosure, a method for fabrication of a display device is provided, the method including: forming a substrate and a passivation layer on the substrate, and forming an anode electrode on the passivation layer; forming a pixel defining layer and a bank structure including a first bank layer and a second bank layer on the anode electrode; removing parts of the bank structure and the pixel defining layer to form the second bank layer to have a tip protruding toward a hole overlapping the anode electrode beyond a side surface of the first bank layer; and forming a light emitting layer, a cathode electrode, and an element inorganic layer on the anode electrode, wherein in the forming of the tip of the second bank layer, the tip of the second bank layer is tilted toward the substrate as it goes (e.g., extends) toward the hole.

In one or more embodiments, the passivation layer may have a side surface forming a first inclination angle with the substrate, and the tilted tip of the second bank layer is formed to cover the inclined side surface of the passivation layer.

In one or more embodiments, the tip of the second bank layer may overlap the inclined side surface of the passivation layer in a direction normal (e.g., perpendicular) to the substrate, and the first inclination angle is equal to or greater than about 20 degrees and equal to or less than about 40 degrees, i.e., in a range of about 20 degrees to about 40 degrees.

In one or more embodiments, in the forming of the light emitting layer and the cathode electrode, the light emitting layer and the cathode electrode may be formed through a deposition and etching process without a separate fine metal mask.

According to one or more embodiments of the disclosure, an electronic device includes at least one display device including: a substrate including an emission area and a non-emission area; a display device housing configured to accommodate the at least one display device; and an optical member configured to magnify a display image of the at least one display device and/or to change an optical path, wherein the at least one display device includes: a passivation layer on (e.g., positioned on) the substrate; an anode electrode on (e.g., positioned on) the passivation layer; a pixel defining layer on (e.g., positioned on) the anode electrode to overlap the non-emission area and defining a first opening; a bank structure on (e.g., positioned on) the pixel defining layer and defining a second opening; a cathode electrode on (e.g., positioned on) the anode electrode and in contact with the bank structure; and an element inorganic layer on (e.g., positioned on) the cathode electrode, wherein the bank structure includes a first bank layer and a second bank layer having a tip protruding toward the first opening beyond a side surface of the first bank layer, and the tip of the second bank layer is tilted toward the substrate as it goes (e.g., extends) toward the first opening.

In accordance with the display device and the method for fabrication thereof according to one or more embodiments, a light emitting layer or a cathode electrode may be formed separately for each emission area without utilizing a separate fine metal mask. Further, in accordance with the display device and the method for fabrication thereof according to one or more embodiments, it may also solve a reliability defect due to moisture permeation.

It should be noted that effects and aspects of the present disclosure are not limited to those described above and other effects and aspects of the present disclosure will be apparent to those skilled in the art from the following descriptions.

### BRIEF DESCRIPTION OF THE DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects and features of the present disclosure will become more apparent and appreciated from the following descriptions of example embodiments thereof with reference to the accompanying drawings, in which:

FIG. 1 is a perspective view illustrating a head mounted electronic device according to one or more embodiments of the present disclosure;

FIG. 2 is an exploded perspective view of the head mounted electronic device of FIG. 1 according to one or more embodiments of the present disclosure;

FIG. 3 is a perspective view illustrating a head mounted electronic device according to one or more embodiments of the present disclosure;

FIG. 4 is an exploded perspective view showing a display device according to one or more embodiments of the present disclosure;

FIG. 5 is a plan view showing a plurality of pixels arranged in the display area of FIG. 4 according to one or more embodiments of the present disclosure;

FIG. 6 is a cross-sectional view of the display panel taken along the line D-D′ of FIG. 5 according to one or more embodiments of the present disclosure;

FIG. 7 is an enlarged cross-sectional view of the display element layer overlapping the first emission area in FIG. 6 according to one or more embodiments of the present disclosure;

FIG. 8 is an enlarged cross-sectional view of the display element layer overlapping the non-emission area located between the first emission area and the second emission area in FIG. 6 according to one or more embodiments of the present disclosure;

FIG. 9 is a cross-sectional view of a display panel taken along the line D-D′ of FIG. 5 according to one or more embodiments of the present disclosure;

FIG. 10 is an enlarged cross-sectional view of a display element layer overlapping a non-emission area located between the first emission area and the second emission area in FIG. 9 according to one or more embodiments of the present disclosure; and

FIG. 11-19 are cross-sectional views schematically illustrating a fabrication method of the display element layer illustrated in FIG. 6 according to one or more embodiments of the present disclosure.

FIG. 20 is a block diagram of an electronic device according to one or more embodiments of the present disclosure.

FIG. 21 is a schematic diagram illustrating electronic devices according to various embodiments of the present disclosure.

### DETAILED DESCRIPTION

The present disclosure will now be described more fully herein with reference to the accompanying drawings, in which one or more embodiments of present disclosure are shown. The disclosure may, however, be embodied in different forms and should not be construed as limited to one or more embodiments set forth herein. Rather, these embodiments are provided so that this disclosure will be thorough and complete, and will fully convey the scope of present disclosure to those skilled in the art.

It is also to be understood that if (e.g., when) a layer is referred to as being “on” another layer or substrate, it may be directly on the other layer or substrate, or one or more intervening layers may also be present therebetween. In contrast, “directly on” may refer to that there are no additional intervening elements or layers between the element or layer and the another element or layer. The same or like reference numbers/letters indicate the same or like components throughout the disclosure, and duplicative descriptions thereof may not be provided for conciseness.

It is to be understood that, although the terms “first,” “second,” and/or the like may be used herein to describe one or more suitable elements, these elements should not be limited by these terms. These terms are used to distinguish one element from another element. For instance, a first element discussed herein could be termed a second element without departing from the teachings of present disclosure. Similarly, the second element could also be termed a first element.

Unless otherwise defined, all terms (including technical and scientific terms) used herein have the same meaning as commonly understood by one of ordinary skill in the art to which the disclosure pertains. It is also to be understood that terms defined in commonly used dictionaries should be interpreted as having meanings consistent with the meanings in the context of the related art, and are expressly defined herein unless they are interpreted in an ideal or overly formal sense.

Hereinafter, embodiments of the present disclosure will be described in more detail with reference to the accompanying drawings.

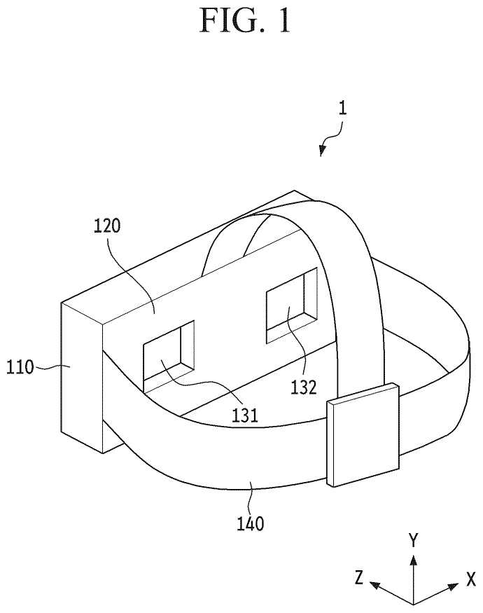

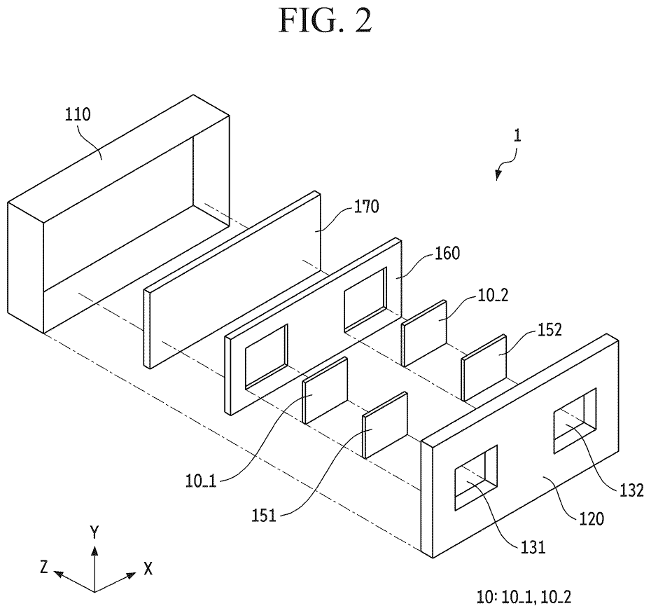

FIG. 1 is a perspective view illustrating a head mounted electronic device according to one or more embodiments of the present disclosure. FIG. 2 is an exploded perspective view of the head mounted electronic device of FIG. 1 according to one or more embodiments of the present disclosure.

Referring to FIG. 1 and FIG. 2, a head mounted electronic device 1 according to one or more embodiments may include a display device 10, a display device housing 110, a housing cover 120, a first eyepiece 131, a second eyepiece 132, a head mounted band 140, a middle frame 160, a first optical member 151, a second optical member 152, and a control circuit board 170.

The display device 10 may include a first display device 10_1 and a second display device 10_2. The first display device 10_1 provides an image to a user's left eye, and the second display device 10_2 provides an image to a user's right eye. A detailed description of the display device 10 will be given later.

The first optical member 151 may be arranged between the first display device 10_1 and the first eyepiece 131, and the second optical member 152 may be arranged between the second display device 10_2 and the second eyepiece 132. Each of the first optical member 151 and the second optical member 152 may include at least one convex lens.

The middle frame 160 may be arranged between the first display device 10_1 and the control circuit board 170, and may be arranged between the second display device 10_2 and the control circuit board 170. The middle frame 160 serves to support and fix the first display device 10_1, the second display device 10_2, and the control circuit board 170.

The control circuit board 170 may be arranged between the middle frame 160 and the display device housing 110. The control circuit board 170 may be connected to the first display device 10_1 and the second display device 10_2 through a connector. The control circuit board 170 may convert an image source inputted from the outside into digital video data, and transmit the digital video data to the first display device 10_1 and the second display device 10_2 through the connector.

In one or more embodiments, the control circuit board 170 may be to transmit the digital video data corresponding to a left eye image improved or optimized for the user's left eye to the first display device 10_1, and may be to transmit the digital video data corresponding to a right eye image improved or optimized for the user's right eye to the second display device 10_2. For example, the control circuit board 170 transmits digital video data for the left eye image, enhanced for the user's left eye, to the first display device 10_1. Similarly, it transmits digital video data for the right eye image, enhanced for the user's right eye, to the second display device 10_2. In one or more embodiments, the control circuit board 170 may be to transmit the same digital video data to the first display device 10_1 and the second display device 10_2.

The display device housing 110 serves to accommodate the display device 10, the middle frame 160, the first optical member 151, the second optical member 152, and the control circuit board 170. The housing cover 120 is arranged to cover one opened surface of the display device housing 110. The housing cover 120 may include the first eyepiece 131 at which the user's left eye looks and the second eyepiece 132 at which the user's right eye looks. For example, the housing cover 120 may include the first eyepiece 131 for the user's left eye and the second eyepiece 132 for the user's right eye. Although it is illustrated in FIG. 1 and FIG. 2 that the first eyepiece 131 and the second eyepiece 132 are arranged separately, embodiments of the present disclosure are not limited thereto. In one or more embodiments, the first eyepiece 131 and the second eyepiece 132 may be integrated into one piece.

The first eyepiece 131 may be aligned with the first display device 10_1 and the first optical member 151, and the second eyepiece 132 may be aligned with the second display device 10_2 and the second optical member 152. Therefore, a user may view the image of the first display device 10_1 magnified as a virtual image by the first optical member 151 through the first eyepiece 131, and may view the image of the second display device 10_2 magnified as a virtual image by the second optical member 152 through the second eyepiece 132.

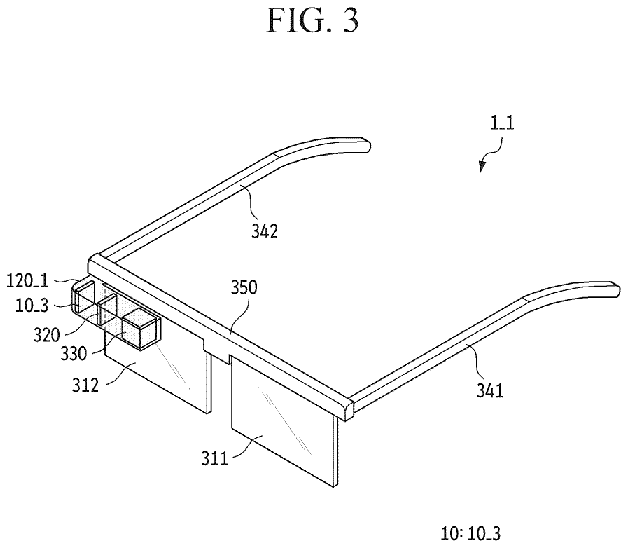

The head mounted band 140 serves to fix the display device housing 110 to a user's head so that the state in which the first eyepiece 131 and the second eyepiece 132 of the housing cover 120 are located at the user's left eye and the user's right eye, respectively, may be maintained. When the display device housing 110 is implemented as a light and small device, the head mounted electronic device 1 may include an eyeglass frame, as shown in FIG. 3, instead of the head mounted band 140.

In one or more embodiments, the head mounted electronic device 1 may further include a battery for supplying a power, an external memory slot capable of storing an external memory, an external connection port for receiving an image source, and a wireless communication module. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 3 is a perspective view illustrating a head mounted electronic device according to one or more embodiments of the present disclosure.

Referring to FIG. 3, a head mounted electronic device 1_1 according to one or more embodiments may be a glasses-type (kind) electronic device in which a display device housing 120_1 is implemented as a light and small device. The head mounted electronic device 1_1 according to one or more embodiments may include the display device 10, a left lens 311, a right lens 312, a support frame 350, temples 341 and 342, an optical member 320, an optical path changing member 330, and the display device housing 120_1.

The display device 10 shown in FIG. 3 may include a third display device 10_3. The third display device 10_3 may be substantially the same as the first display device 10_1 and the second display device 10_2 shown in FIG. 2.

The display device housing 120_1 may include the display device 10, the optical member 320, and the optical path changing member 330. An image displayed on the display device 10 may be magnified by the optical member 320, and the optical path thereof may be changed by the optical path changing member 330 to provide the image to the user's right eye through the right eye lens 312. Accordingly, the user may view an augmented reality image, through the right eye, in which a virtual image displayed on the display device 10 and a real image seen through the right lens 312 are combined.

Although it is illustrated in FIG. 3 that the display device housing 120_1 is arranged at the right end of the support frame 350, embodiments of the present disclosure are not limited thereto. For example, in one or more embodiments, the display device housing 120_1 may be arranged at the left end of the support frame 350, and in these embodiments, the image of the display device 10 may be provided to the user's left eye. In one or more embodiments, the display device housing 120_1 may be arranged at both (e.g., simultaneously) the left end and the right end of the support frame 350, and in these embodiments, the user may view the image displayed on the display device 10 through both (e.g., simultaneously) the left eye and the right eye.

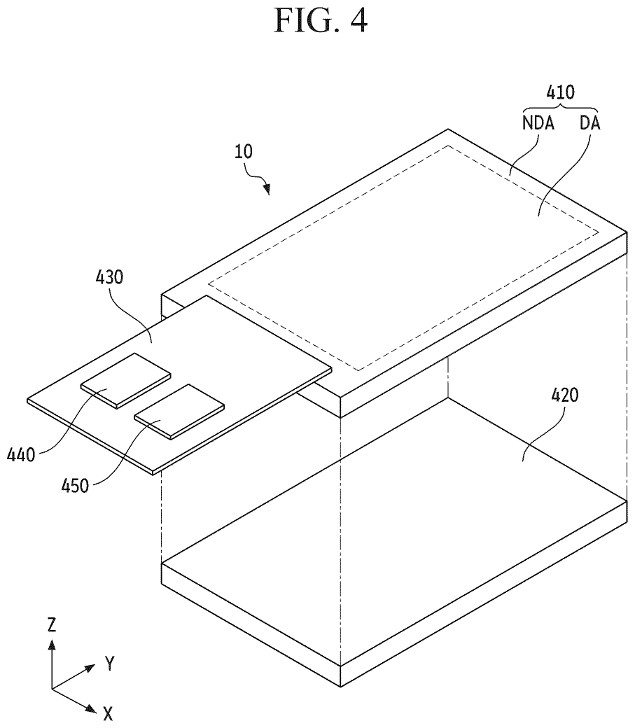

FIG. 4 is an exploded perspective view showing the display device 10 according to one or more embodiments of the present disclosure.

Referring to FIG. 4, the display device 10 according to one or more embodiments is a device displaying a moving image or a still image. The display device 10 according to one or more embodiments may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC), and/or the like. For example, the display device 10 may be applied as a display unit of a television, a laptop, a monitor, a billboard, or an Internet-of-Things (IoT) device. In one or more embodiments, the display device 10 may be applied to a smart watch, a watch phone, a head mounted display (HMD) for implementing virtual reality and/or augmented reality, and/or the like.

The display device 10 according to one or more embodiments includes a display panel 410, a heat dissipation layer 420, a circuit board 430, a driving circuit 440, and a power supply circuit 450.

In one or more embodiments, the display panel 410 may have a planar shape, for example, similar to a quadrilateral shape. For example, the display panel 410 may have a planar shape similar to a quadrilateral shape having short sides in a first direction X and long sides in a second direction Y intersecting the first direction X. In the display panel 410, a corner where a short side in the first direction X and a long side in the second direction Y meet may be right-angled or rounded with a set or predetermined curvature. The planar shape of the display panel 410 is not limited to a quadrilateral shape, and may be a shape similar to another polygonal shape, a circular shape, or an elliptical shape. A planar shape of the display device 10 may follow the planar shape of the display panel 410, but embodiments of the present disclosure are not limited thereto.

A display area DA may be positioned in the center of the display panel 410 and may occupy most of the area of the display panel 410. A non-display area NDA may be around (e.g., surround) an edge of the display area DA.

The heat dissipation layer 420 may overlap the display panel 410 in a third direction Z that is a thickness direction of the display panel 410. The heat dissipation layer 420 may be arranged on a (e.g., one) surface, for example, a rear surface of the display panel 410. The heat dissipation layer 420 serves to dissipate heat generated from the display panel 410. The heat dissipation layer 420 may include a metal layer having high thermal conductivity, such as graphite, silver (Ag), copper (Cu), and/or aluminum (Al).

The circuit board 430 may be positioned on the non-display area NDA of the display panel 410 by using a conductive adhesive member such as an anisotropic conductive film. In one or more embodiments, the circuit board 430 may be a flexible printed circuit board having a flexible material, or a flexible film. Although it is illustrated in FIG. 4 that the circuit board 430 is unfolded, the circuit board 430 may be bent. In these embodiments, one end of the circuit board 430 may be arranged on the rear surface of the display panel 410. The one end of the circuit board 430 may be opposite to the other end of the circuit board 430 connected to a plurality of pads of a pad area of the display panel 410 by using a conductive adhesive member.

The driving circuit 440 may receive digital video data and timing signals from the outside. The driving circuit 440 may generate a scan timing control signal, an emission timing control signal, and a data timing control signal for controlling the display panel 410 in response to the timing signals.

The power supply circuit 450 may generate a plurality of panel driving voltages in response to a power voltage from the outside. For example, the power supply circuit 450 may generate and supply a first driving voltage (e.g., a low potential voltage), a second driving voltage (e.g., a high potential voltage), and a third driving voltage (e.g., an initialization voltage) to the display panel 410.

Each of the driving circuit 440 and the power supply circuit 450 may be formed as an integrated circuit (IC) and attached to a (e.g., one) surface of the circuit board 430.

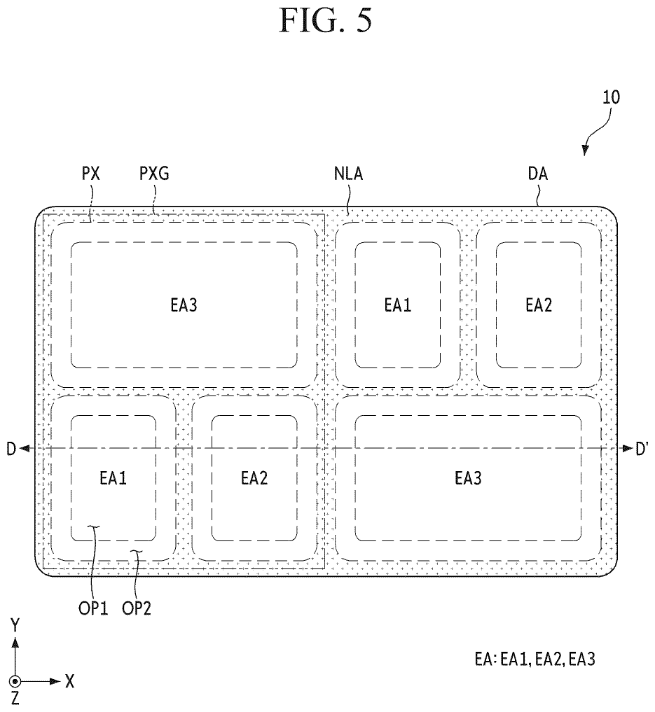

FIG. 5 is a plan view showing a plurality of pixels arranged in the display area of FIG. 4 according to one or more embodiments of the present disclosure.

Referring to FIG. 5, the display area DA included in the display device 10 of one or more embodiments may include an emission area EA and a non-emission area NLA. The emission area EA may include a first emission area EA1, a second emission area EA2, and a third emission area EA3 that are spaced and/or apart (e.g., spaced apart or separated) from one another. The non-emission area NLA may be arranged to be around (e.g., surround) each of the first emission area EA1, the second emission area EA2, and the third emission area EA3. The non-emission area NLA may assist in preventing or reducing the respective lights emitted from the first emission area EA1, the second emission area EA2, and the third emission area EA3 from being mixed.

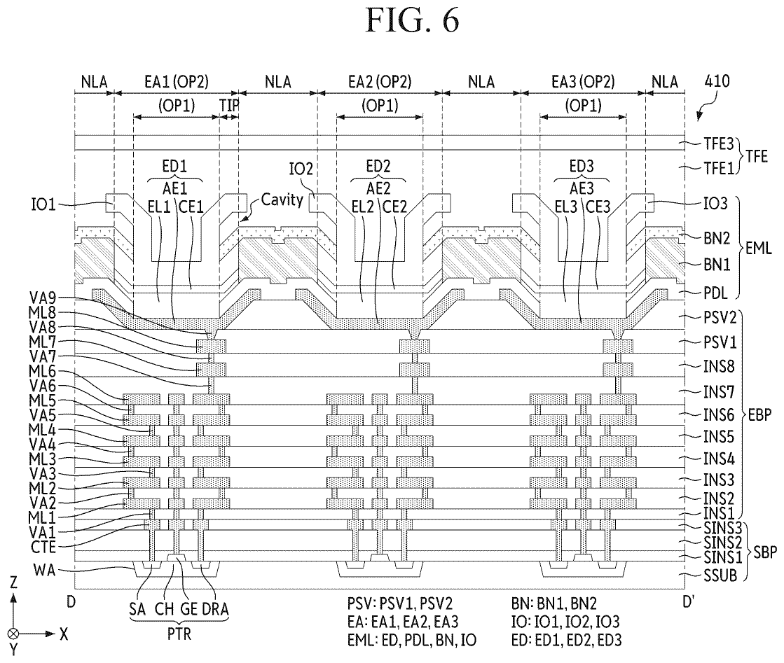

The first emission area EA1, the second emission area EA2, and the third emission area EA3 may be to emit light of different colors. The color of light emitted from each of the first emission area EA1, the second emission area EA2, and the third emission area EA3 may be different according to the type (kind) of the light emitting element ED (see FIG. 6) which will be described in more detail later. For example, in one or more embodiments, the first emission area EA1 may be to emit red light, the second emission area EA2 may be to emit green light, and the third emission area EA3 may be to emit blue light, but embodiments of the present disclosure are not limited thereto. The sizes and shapes of the first emission area EA1, the second emission area EA2, and the third emission area EA3 may be freely and suitably adjusted according to desired or required characteristics.

A plurality of pixels PX may be located in a portion overlapping the emission area EA. The pixels PX may be spaced and/or apart (e.g., spaced apart or separated) from each other.

In one or more embodiments, the pixel PX overlapping at least one first emission area EA1, the pixel PX overlapping at least one second emission area EA2, and the pixel PX overlapping at least one third emission area EA3 may constitute one pixel group PXG. The pixel group PXG may be a minimum unit that emits white light (e.g., combined white light). However, the type (kind) and/or number of each of the first emission area EA1, the second emission area EA2, and the third emission area EA3 constituting the pixel group PXG may vary according to one or more embodiments.

The emission area EA may be defined by a first opening OP1 and a second opening OP2. In plan view, the second opening OP2 may completely be around (e.g., surround) the first opening OP1. In the context of the present disclosure and unless defined otherwise, “In plan view” refers to a view from above, looking down on an object or layout. For example, it refers to viewing the openings and structures as if looking at them from directly above. The first opening OP1 may be defined by a pixel defining layer PDL (see FIG. 6) that will be described in more detail later, and the second opening OP2 may be defined by a bank structure BN (see FIG. 6) that will be described in more detail later. A detailed description thereof will be described in more detail later.

FIG. 6 is a cross-sectional view of the display panel taken along the line D-D′ of FIG. 5 according to one or more embodiments of the present disclosure.

Referring to FIG. 6, the display panel 410 may include a semiconductor backplane SBP, a light emitting element backplane EBP, a display element layer EML, and an encapsulation layer TFE. According to one or more embodiments, the display panel 410 may further include an optical layer and/or an optical film for improving optical characteristics, a touch sensor layer for providing touch characteristics, and/or the like on the encapsulation layer TFE.

The semiconductor backplane SBP may include a substrate SSUB, a plurality of pixel transistors PTR, a plurality of first to third semiconductor insulating layers SINS1 to SINS3, and a plurality of contact terminals CTE.

The substrate SSUB may be a silicon substrate, a germanium substrate, or a silicon-germanium substrate. The substrate SSUB may be a substrate doped with first type (kind) impurities. A plurality of well regions WA may be located in the top surface (e.g., top surface layer) of the substrate SSUB. The plurality of well regions WA may be regions doped with a second type (kind) impurity. The second type (kind) impurity may be different from the aforementioned first type (kind) impurity. For example, in one or more embodiments, if (e.g., when) the first type (kind) impurity is a p-type (kind) impurity, the second type (kind) impurity may be an n-type (kind) impurity. In one or more embodiments, if (e.g., when) the first type (kind) impurity is an n-type (kind) impurity, the second type (kind) impurity may be a p-type (kind) impurity.

In one or more embodiments, the substrate SSUB may be replaced with a glass substrate or a polymer resin substrate such as a polyimide. In these embodiments, thin film transistors may be located on the glass substrate or the polymer resin substrate. The glass substrate may be a rigid substrate that does not bend, and the polymer resin substrate may be a flexible substrate that can be bent or curved.

Each of the plurality of well regions WA may include a source region SA corresponding to a source electrode, a drain region DRA corresponding to a drain electrode, and a channel region CH arranged between the source region SA and the drain region DRA.

Each of the source region SA and the drain region DRA may be a region doped with the first type (kind) impurity. A gate electrode GE of the pixel transistor PTR may overlap the well region WA in the third direction (Z-axis direction). The channel region CH may overlap the gate electrode GE in the third direction (Z-axis direction) with an insulating layer interposed therebetween, the insulating layer being omitted in FIG. 6 for clarity and conciseness. The source region SA may be located on one side of the gate electrode GE, and the drain region DRA may be arranged on the other side of the gate electrode GE.

A first semiconductor insulating layer SINS1 may be located on the substrate SSUB. The first semiconductor insulating layer SINS1 may include an inorganic insulating material, for example, at least one of silicon oxide, silicon nitride, silicon oxynitride, or aluminum oxide.

A second semiconductor insulating layer SINS2 may be located on the first semiconductor insulating layer SINS1. In one or more embodiments, the second semiconductor insulating layer SINS2 may include the same material as the first semiconductor insulating layer SINS1.

The plurality of contact terminals CTE may be located on the second semiconductor insulating layer SINS2. Each of the plurality of contact terminals CTE may be connected to one of the gate electrode GE, the source region SA, and the drain region DRA of each of the pixel transistors PTR through holes penetrating the first semiconductor insulating layer SINS1 and the second semiconductor insulating layer SINS2.

The contact terminal CTE may be formed of any one selected from among copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating layer SINS3 may be located on a side surface of each of the plurality of contact terminals CTE. A top surface of each of the plurality of contact terminals CTE may be exposed without being covered by the third semiconductor insulating layer SINS3. In one or more embodiments, the third semiconductor insulating layer SINS3 may include the same material as the first semiconductor insulating layer SINS1.

The light emitting element backplane EBP may be arranged on the semiconductor backplane SBP. The light emitting element backplane EBP may include first to eighth metal layers ML1 to ML8, first to ninth vias VA1 to VA9, first to eighth interlayer insulating layers INS1 to INS8, and a passivation layer PSV. In one or more embodiments, the passivation layer PSV may include a first passivation layer PSV1 and a second passivation layer PSV2.

The first to eighth metal layers ML1 to ML8 may be made of substantially the same material as the first to ninth vias VA1 to VA9. The first to eighth metal layers ML1 to ML8 and the first to ninth vias VA1 to VA9 may each be formed of any one selected from among copper (Cu), aluminum (Al), tungsten (W), molybdenum (Mo), chromium (Cr), gold (Au), titanium (Ti), nickel (Ni), and neodymium (Nd), or an alloy including any one of them.

The first to eighth metal layers ML1 to ML8 serve to connect the plurality of contact terminals CTE exposed from the semiconductor backplane SBP to thereby implement the circuit of the pixel PX.

The first interlayer insulating layer INS1 may be located on the semiconductor backplane SBP. The first via VA1 may penetrate the first interlayer insulating layer INS1 and be connected to the contact terminal CTE. The plurality of first metal layers ML1 may be arranged on the first interlayer insulating layer INS1 and may each be connected to the first via VA1.

The second interlayer insulating layer INS2 may be located on the first interlayer insulating layer INS1 and the first metal layers ML1. Each of the second vias VA2 may penetrate the second interlayer insulating layer INS2 and be connected to the exposed first metal layer ML1. Each of the plurality of second metal layers ML2 may be arranged on the second interlayer insulating layer INS2 and may be connected to the second via VA2.

The third interlayer insulating layer INS3 may be located on the second interlayer insulating layer INS2 and the second metal layers ML2. Each of the third vias VA3 may penetrate the third interlayer insulating layer INS3 and be connected to the exposed second metal layer ML2. Each of the plurality of third metal layers ML3 may be arranged on the third interlayer insulating layer INS3 and may be connected to the third via VA3.

The fourth interlayer insulating layer INS4 may be located on the third interlayer insulating layer INS3 and the third metal layers ML3. Each of the fourth vias VA4 may penetrate the fourth interlayer insulating layer INS4 and be connected to the exposed third metal layer ML3. Each of the plurality of fourth metal layers ML4 may be arranged on the fourth interlayer insulating layer INS4 and may be connected to the fourth via VA4.

The fifth interlayer insulating layer INS5 may be located on the fourth interlayer insulating layer INS4 and the fourth metal layers ML4. Each of the fifth vias VA5 may penetrate the fifth interlayer insulating layer INS5 and be connected to the exposed fourth metal layer ML4. Each of the plurality of fifth metal layers ML5 may be arranged on the fifth interlayer insulating layer INS5 and may be connected to the fifth via VA5.

The sixth interlayer insulating layer INS6 may be located on the fifth interlayer insulating layer INS5 and the fifth metal layers ML5. Each of the sixth vias VA6 may penetrate the sixth interlayer insulating layer INS6 and be connected to the exposed fifth metal layer ML5. Each of the plurality of sixth metal layers ML6 may be arranged on the sixth interlayer insulating layer INS6 and may be connected to the sixth via VA6.

The seventh interlayer insulating layer INS7 may be located on the sixth interlayer insulating layer INS6 and the sixth metal layers ML6. Each of the seventh vias VA7 may penetrate the seventh interlayer insulating layer INS7 and be connected to the exposed sixth metal layer ML6. Each of the plurality of seventh metal layers ML7 may be arranged on the seventh interlayer insulating layer INS7 and may be connected to the seventh via VA7.

The eighth interlayer insulating layer INS8 may be located on the seventh interlayer insulating layer INS7 and the seventh metal layers ML7. Each of the eighth vias VA8 may penetrate the eighth interlayer insulating layer INS8 and be connected to the exposed seventh metal layer ML7. Each of the plurality of eighth metal layers ML8 may be arranged on the eighth interlayer insulating layer INS8 and may be connected to the eighth via VA8.

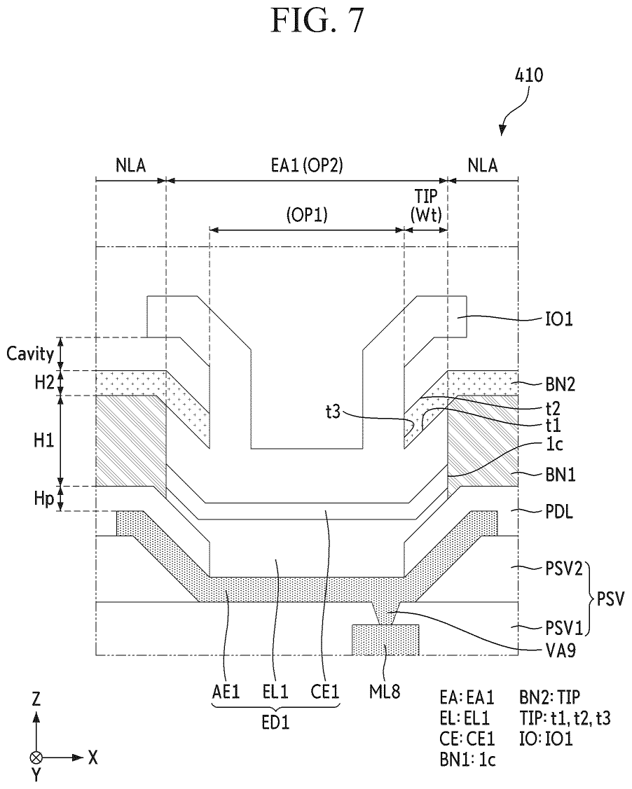

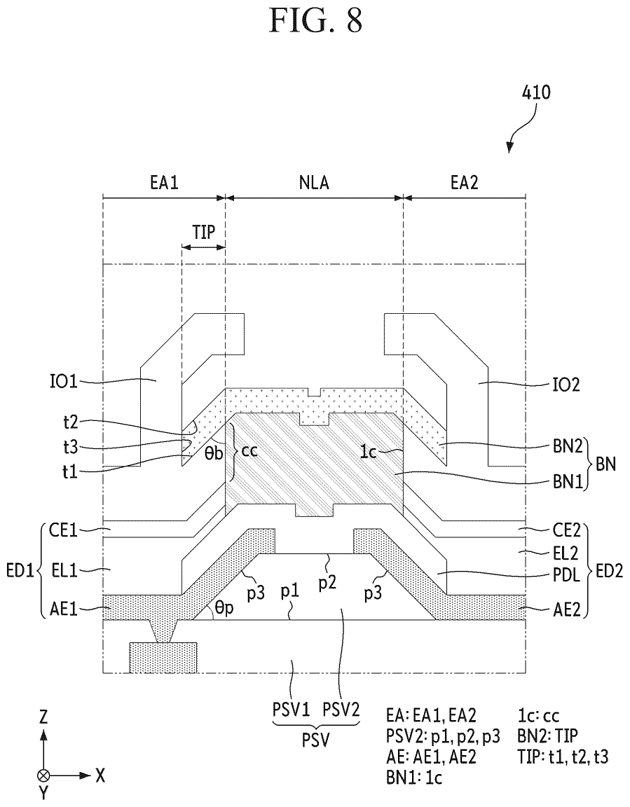

FIG. 7 is an enlarged cross-sectional view of the display element layer overlapping the first emission area in FIG. 6. FIG. 8 is an enlarged cross-sectional view of the display element layer overlapping the non-emission area located between the first emission area and the second emission area in FIG. 6.

Referring to FIGS. 6 to 8, the first passivation layer PSV1 may be located on the eighth interlayer insulating layer INS8. The first passivation layer PSV1 may be commonly referred to as a via layer. The first passivation layer PSV1 may flatten the lower structure of the display panel 410.

The first passivation layer PSV1 may include an organic insulating material. For example, the first passivation layer PSV1 may include an acrylic resin, a polyimide, a polyamide, a benzocyclobutene-based resin, a phenol resin, and/or the like. Each of the ninth vias VA9 may penetrate the first passivation layer PSV1 and be connected to the exposed eighth metal layer ML8.

In one or more embodiments, the second passivation layer PSV2 may be arranged on the first passivation layer PSV1. The second passivation layer PSV2 may be located in a portion overlapping the non-emission area NLA while around (e.g., surrounding) the emission area EA.

The second passivation layer PSV2 may have a shape that protrudes in a direction toward the display element layer EML. For example, the second passivation layer PSV2 may have a convex shape to one side of the third direction (Z-axis direction), i.e., in a direction toward the encapsulation layer TFE.

In one or more embodiments, the second passivation layer PSV2 may include a first surface p1, a second surface p2, and a side surface p3. The first surface p1 may be a surface opposite to (e.g., adjacent to or facing) the first passivation layer PSV1, the second surface p2 may be a surface opposite to the first surface p1, and the side surface p3 may be a surface located to face the emission area EA. The side surface p3 may be a surface connecting the first surface p1 and the second surface p2 to each other. For example, in one or more embodiments, the second passivation layer PSV2 may have a trapezoidal shape.

In one or more embodiments, a width of the first surface p1 may be greater than a width of the second surface p2 in the first direction (X-axis direction). In addition, the side surface p3 may be an inclined surface. For example, the side surface p3 may be an inclined surface that forms a first inclination angle θp with the first surface p1. For example, in one or more embodiments, the first inclination angle θp may be in a range of about 20° to about 40°.

In one or more embodiments, the second passivation layer PSV2 may assist in forming a tip TIP of the second bank layer BN2 to be tilted during a manufacturing process. A detailed description thereof will be described in more detail later.

The display element layer EML may be located on the light emitting element backplane EBP. The display element layer EML may include the emission area EA and the non-emission area NLA. It may further include a light emitting element ED, a pixel defining layer PDL, and a bank structure BN and an element inorganic layer IO each in a portion overlapping the emission area EA and the non-emission area NLA.

The light emitting element ED of one or more embodiments may include a first light emitting element ED1 arranged in the first emission area EA1, a second light emitting element ED2 arranged in the second emission area EA2, and a third light emitting element ED3 arranged in the third emission area EA3.

The first light emitting element ED1 may include a first anode electrode AE1, a first light emitting layer EL1, and a first cathode electrode CE1, the second light emitting element ED2 may include a second anode electrode AE2, a second light emitting layer EL2, and a second cathode electrode CE2, and the third light emitting element ED3 may include a third anode electrode AE3, a third light emitting layer EL3, and a third cathode electrode CE3.

The first light emitting element ED1, the second light emitting element ED2, and the third light emitting element ED3 may be to emit light of different colors according to a material of the light emitting layer EL contained therein. For example, in one or more embodiments, the first light emitting element ED1 may be to emit red light, the second light emitting element ED2 may be to emit green light, and the third light emitting element ED3 may be to emit blue light.

An anode electrode AE of the display panel 410 may be arranged on the passivation layer PSV. The anode electrode AE may be located to overlap the emission area EA and the non-emission area NLA. The anode electrode AE may be electrically connected to the drain region DRA of the pixel transistor PTR through the ninth via VA9 penetrating the first passivation layer PSV1.

The anode electrode AE may include a transparent electrode material or/and a conductive metal material. For example, in one or more embodiments, the anode electrode AE may contain one or more selected from among silver (Ag), copper (Cu), aluminum (Al), nickel (Ni), lanthanum (La), titanium (Ti), and titanium nitride (TiN). In one or more embodiments, the anode electrode AE may contain one or more selected from among indium tin oxide (ITO), indium zinc oxide (IZO), and indium tin zinc oxide (ITZO). In one or more embodiments, the anode electrode AE may have a multilayer structure having a metal material layer and a transparent electrode material layer.

In one or more embodiments, the anode electrode AE may cover the first passivation layer PSV1 and the second passivation layer PSV2 along the profiles thereof, and may be located on the side surface p3 of the second passivation layer PSV2 while being in contact therewith. Accordingly, the anode electrode AE may have an inclined surface parallel to (e.g., substantially parallel to) the side surface p3 of the second passivation layer PSV2.

The anode electrode AE may include the first anode electrode AE1 located in the first emission area EA1, the second anode electrode AE2 located in the second emission area EA2, and the third anode electrode AE3 located in the third emission area EA3. The first anode electrode AE1, the second anode electrode AE2, and the third anode electrode AE3 may be spaced and/or apart (e.g., spaced apart or separated) from one another on the second passivation layer PSV2 and insulated from one another by the pixel defining layer PDL.

In one or more embodiments, the pixel defining layer PDL may be arranged on the anode electrode AE and the passivation layer PSV. The pixel defining layer PDL may cover a portion of the anode electrode AE and the passivation layer PSV along the profiles thereof. Accordingly, the pixel defining layer PDL may have an inclined surface parallel to (e.g., substantially parallel to) the side surface p3 of the second passivation layer PSV2.

In one or more embodiments, a height Hp of the pixel defining layer PDL may be in a range of about 200 nanometers (nm) to about 300 nm.

The pixel defining layer PDL may define the first opening OP1. The pixel defining layer PDL may expose a part of the anode electrode AE in a portion overlapping the first opening OP1. For example, the pixel defining layer PDL may be located to be around (e.g., surround) the first opening OP1.

The pixel defining layer PDL may include an inorganic insulating material. For example, in one or more embodiments, the pixel defining layer PDL may include any one selected from among aluminum oxide, titanium oxide, tantalum oxide, hafnium oxide, zinc oxide, silicon oxide, silicon nitride, and silicon oxynitride.

In one or more embodiments, the pixel defining layer PDL may be in contact with a part of the second surface p2 of the second passivation layer PSV2.

The bank structure BN of one or more embodiments may be located on the pixel defining layer PDL at a portion overlapping the non-emission area NLA. The bank structure BN may define the second opening OP2. The bank structure BN may cover the second passivation layer PSV2 and the pixel defining layer PDL along the profiles thereof. Accordingly, the bank structure BN may have an inclined surface parallel to (e.g., substantially parallel to) the side surface p3 of the second passivation layer PSV2.

The bank structure BN may include a first bank layer BN1 and a second bank layer BN2 including different metal materials and structures and having different roles.

In one or more embodiments, the first bank layer BN1 may be located on the pixel defining layer PDL. The first bank layer BN1 may include a metal with high electrical conductivity. As an example, in one or more embodiments, the first bank layer BN1 may include aluminum (Al).

The first bank layer BN1 may serve to electrically connect the first cathode electrode CE1, the second cathode electrode CE2, and the third cathode electrode CE3 to one another, which are located in the first emission area EA1, the second emission area EA2, and the third emission area EA3, respectively.

In one or more embodiments, the first bank layer BN1 may include a side surface 1c adjacent to (e.g., facing) the emission area EA. The light emitting layer EL and the cathode electrode CE may each be in contact with the side surface 1c of the first bank layer BN1. A detailed description thereof will be described in more detail later.

The second bank layer BN2 of one or more embodiments may be positioned on the first bank layer BN1. The second bank layer BN2 may include a material with a lower etching rate than the material included in the first bank layer BN1. As an example, in one or more embodiments, the second bank layer BN2 may contain titanium (Ti).

In one or more embodiments, a height H1 of the first bank layer BN1 may be greater than a height H2 of the second bank layer BN2. For example, in one or more embodiments, the height H1 of the first bank layer BN1 may be in a range of about 500 nm to about 700 nm, and the height H2 of the second bank layer BN2 may be a range of about 200 nm to about 300 nm.

In one or more embodiments, the second bank layer BN2 may include a tip TIP that protrudes toward the first opening OP1 beyond the side surface 1c of the first bank layer BN1. An undercut may be formed between the tip TIP of the second bank layer BN2 and the side surface 1c of the first bank layer BN1. The tip TIP of the second bank layer BN2 may be formed due to different etching rates for the first bank layer BN1 and the second bank layer BN2 during a manufacturing process. The manufacturing process will be described in more detail later.

In general, a high-resolution display device may have a relatively narrow gap between neighboring light emitting elements ED. Therefore, it may be difficult to form a plurality of light emitting elements ED included in a high-resolution display device using a fine metal mask during the manufacturing process.

In the display device 10 of one or more embodiments, as the second bank layer BN2 includes the tip TIP protruding toward the emission area EA, the first light emitting element ED1, the second light emitting element ED2, and the third light emitting element ED3, which respectively overlap the first emission area EA1, the second emission area EA2, and the third emission area EA3, may be formed without a separate fine metal mask during the manufacturing process. The manufacturing process will be described in more detail later.

In one or more embodiments, a width Wt of the tip TIP of the second bank layer BN2 may be in a range of about 500 nm to about 1000 nm.

In one or more embodiments, the tip TIP of the second bank layer BN2 may overlap the side surface p3 of the second passivation layer PSV2 in the third direction (Z-axis direction).

In one or more embodiments, the tip TIP of the second bank layer BN2 may include a first surface t1, a second surface t2, and a side surface t3. The first surface t1 may be a surface opposite to (e.g., adjacent to or facing) the first bank layer BN1, the second surface t2 may be a surface opposite to the first surface t1, and the side surface t3 may be a surface facing the emission area EA and connecting the first surface t1 to the second surface t2.

The first surface t1 and the second surface t2 of the second bank layer BN2 may each be an inclined surface. For example, in one or more embodiments, the first surface t1 and the second surface t2 of the second bank layer BN2 may each be an inclined surface that is tilted in a direction parallel to (e.g., substantially parallel to) the side surface p3 of the second passivation layer PSV2. Accordingly, the tip TIP of the second bank layer BN2 may have a shape tilted to the other side of the third direction (Z-axis direction) as it goes (e.g., extends) toward the first opening OP1.

The other side of the third direction (Z-axis direction) as used herein may be the same direction as a direction toward the anode electrode AE, a direction toward the first bank layer BN1, or a direction toward the pixel defining layer PDL, or the opposite direction of the Z-axis direction. In the context of the present disclosure and unless defined otherwise, “the other side of the third direction (Z-axis direction)” refers to the direction opposite to the positive Z-axis direction. For example, it refers to that the tip of the bank structure BN is tilted away from the positive Z-axis direction, towards the negative Z-axis direction. This direction is aligned with the direction towards the anode electrode AE, the first bank layer BN1, or the pixel defining layer PDL.

In one or more embodiments, the tip TIP of the second bank layer BN2 and the first bank layer BN1 may form a second inclination angle θb. For example, in one or more embodiments, the first surface t1 included in the tip TIP of the second bank layer BN2 and the side surface 1c of the first bank layer BN1 may form the second inclination angle θb. For example, in one or more embodiments, the second inclination angle θb may be in a range of about 20° to about 40°.

The bank structure BN of the display panel 410 may cover the second passivation layer PSV2 along the shape thereof during the manufacturing process. For example, the bank structure BN of the display panel 410 may cover the second passivation layer PSV2 along its shape during the manufacturing process. Therefore, it may have the tip TIP tilted in the direction (substantially) parallel with the side surface p3 of the second passivation layer PSV2. For example, the bank structure BN of the display panel 410 may have the tip TIP that is tilted to the other side of the third direction (Z-axis direction) as it goes (extends) toward the first opening OP1, without utilizing a separate physical process. For example, the bank structure BN of the display panel 410 may have the tip TIP tilted towards the negative Z-axis direction as it extends toward the first opening OP1, without utilizing a separate physical process. Accordingly, the display panel 410 may be easily manufactured. The manufacturing process will be described in more detail later.

The light emitting layer EL of one or more embodiments may be located on the anode electrode AE. In one or more embodiments, the light emitting layer EL may be an organic light emitting layer made of an organic material, and may be formed on the anode electrode AE by a deposition process. In the light emitting layer EL, if (e.g., when) the pixel transistor PTR applies a high potential voltage to the anode electrode AE, and the cathode electrode CE receives a low potential voltage, holes and electrons may move to the light emitting layer EL through a hole transport layer and an electron transport layer, respectively, and may be combined with each other to emit light in the light emitting layer EL.

The light emitting layer EL may include the first light emitting layer EL1, the second light emitting layer EL2, and the third light emitting layer EL3 arranged in the first emission area EA1, the second emission area EA2, and the third emission area EA3, respectively. The first light emitting layer EL1 may be located on the first anode electrode AE1 in the first emission area EA1, the second light emitting layer EL2 may be arranged on the second anode electrode AE2 in the second emission area EA2, and the third light emitting layer EL3 may be arranged on the third anode electrode AE3 in the third emission area EA3.

The first light emitting layer EL1, the second light emitting layer EL2, and the third light emitting layer EL3 may be to emit different colors. For example, in one or more embodiments, the first light emitting layer EL1 may be to emit red light, the second light emitting layer EL2 may be to emit green light, and the third light emitting layer EL3 may be to emit blue light.

In one or more embodiments, the light emitting layer EL may completely cover the pixel defining layer PDL in a portion overlapping the second opening OP2. In addition, the light emitting layer EL may be in contact with the side surface 1c of the first bank layer BN1 in a portion overlapping the second opening OP2. However, in the display panel 410 of one or more embodiments, the tip TIP of the second bank layer BN2 has a shape tilted to the other side of the third direction (Z-axis direction), so that it may assist in preventing or reducing residues of materials forming the light emitting layer EL from being deposited on an upper surface cc of the side surface 1c and the tip TIP. Accordingly, the display panel 410 may solve a reliability defect due to moisture permeation caused by residues of the (organic) materials forming the light emitting layer EL.

The cathode electrode CE of one or more embodiments may be located on the light emitting layer EL. The cathode electrode CE may include a transparent conductive material, so that the light generated in the light emitting layer EL may be emitted. The cathode electrode CE may receive a common voltage or a low potential voltage.

The cathode electrode CE may include the first cathode electrode CE1, the second cathode electrode CE2, and the third cathode electrode CE3 respectively arranged in the first emission area EA1, the second emission area EA2, and the third emission area EA3. The first cathode electrode CE1 may be arranged on the first light emitting layer EL1 in the first emission area EA1, the second cathode electrode CE2 may be arranged on the second light emitting layer EL2 in the second emission area EA2, and the third cathode electrode CE3 may be located on the third light emitting layer EL3 in the third emission area EA3. The first cathode electrode CE1, the second cathode electrode CE2, and the third cathode electrode CE3 may be spaced and/or apart (e.g., spaced apart or separated) from one another with the bank structure BN interposed therebetween.

The cathode electrode CE may completely cover the light emitting layer EL in a portion overlapping the second opening OP2. In addition, the cathode electrode CE may be in contact with the side surface 1c of the first bank layer BN1.

However, in the display panel 410 of one or more embodiments, the tip TIP of the second bank layer BN2 has a shape tilted to the other side of the third direction (Z-axis direction), so that it may assist in preventing or reducing residues of a material (e.g., conductive material) forming the cathode electrode CE from being deposited on the upper surface cc of the side surface 1c and the tip TIP. Accordingly, the display panel 410 may solve a reliability defect due to moisture permeation caused by residues of the conductive material (e.g., metal material) forming the cathode electrode CE.

In one or more embodiments, the element inorganic layer IO may be arranged on the light emitting element ED. The element inorganic layer IO covers the light emitting element ED, thereby reducing or preventing oxygen or moisture from penetrating into the light emitting element ED.

The element inorganic layer IO may contain an inorganic insulating material. For example, in one or more embodiments, the element inorganic layer IO may contain any one selected from among silicon nitride, silicon oxide, and silicon oxynitride.

The element inorganic layer IO may include a first element inorganic layer IO1, a second element inorganic layer IO2, and a third element inorganic layer IO3. The first element inorganic layer IO1 may be arranged on the first light emitting element ED1 in the first emission area EA1, the second element inorganic layer IO2 may be arranged on the second light emitting element ED2 in the second emission area EA2, and the third element inorganic layer IO3 may be arranged on the third light emitting element ED3 in the third emission area EA3. The first element inorganic layer IO1, the second element inorganic layer IO2, and the third element inorganic layer IO3 may be spaced and/or apart (e.g., spaced apart or separated) from one another in a portion (e.g., in a region) overlapping the non-emission area NLA. For example, a part of the second bank layer BN2 may not overlap the element inorganic layer IO in the third direction (Z-axis direction) in a portion overlapping the non-emission area NLA.

In the drawings, the first element inorganic layer IO1, the second element inorganic layer IO2, and the third element inorganic layer IO3 are located in substantially the same layer, so that they may be expected as being formed in substantially the same process. However, in the manufacturing process, the first element inorganic layer IO1, the second element inorganic layer IO2, and the third element inorganic layer IO3 may be sequentially formed in different steps. The manufacturing process will be described in more detail later.

The element inorganic layer IO may be in overall contact with the light emitting element ED to cover it in a portion overlapping the first opening OP1, and may be in contact with the undercut portion, which is formed by the tip TIP of the second bank layer BN2, to cover it in a portion overlapping the second opening OP2. For example, the element inorganic layer IO (e.g., the first element inorganic layer IO1) may be in contact with and cover the side surface 1c of the first bank layer BN1 and the first surface t1 and the side surface t3 included in the tip TIP of the second bank layer BN2.

In portions overlapping the second opening OP2 and the non-emission area NLA, the element inorganic layer IO may be separated from the second bank layer BN2 with a cavity (e.g., an undercut) interposed therebetween in the third direction (Z-axis direction). For example, in one or more embodiments, the element inorganic layer IO (e.g., the first element inorganic layer IO1) may be separated from the second surface t2 of the second bank layer BN2 with the cavity (e.g., undercut) interposed therebetween in the third direction (Z-axis direction). The shape of the cavity (e.g., undercut) may be formed along the tilted shape of the tip TIP of the second bank layer BN2.

The cavity (e.g., undercut) formed between the element inorganic layer IO and the second bank layer BN2 may be formed by removing the material(s) forming the light emitting layer EL and the material(s) forming the cathode electrode CE which are formed temporarily on the second bank layer BN2 during the manufacturing process. The manufacturing process will be described in more detail later.

The encapsulation layer TFE of one or more embodiments may be arranged on the display element layer EML. The encapsulation layer TFE may include an organic encapsulation layer TFE1 and an inorganic encapsulation layer TFE3.

The organic encapsulation layer TFE1 of one or more embodiments may be arranged on the element inorganic layer IO. For example, the organic encapsulation layer TFE1 may be in overall contact with the first element inorganic layer IO1, the second element inorganic layer IO2, and the third element inorganic layer IO3 to cover them.

The organic encapsulation layer TFE1 may flatten a stepped portion formed according to the profile of the lower structure of the display panel 410. In addition, the organic encapsulation layer TFE1 may fill the cavity (e.g., undercut) formed between the second bank layer BN2 and the element inorganic layer IO in a portion overlapping the emission area EA.

The organic encapsulation layer TFE1 may include a polymer-based material. For example, in one or more embodiments, the organic encapsulation layer TFE1 may include an acrylic resin, a silicone resin, an epoxy resin, a silicone acrylic resin, a polyimide, polyethylene, and/or the like.

In one or more embodiments, the inorganic encapsulation layer TFE3 may be arranged on the organic encapsulation layer TFE1. The inorganic encapsulation layer TFE3 may protect the lower structure from permeation of moisture and/or oxygen.

The inorganic encapsulation layer TFE3 may contain an inorganic insulating material. For example, in one or more embodiments, the inorganic encapsulation layer TFE3 may contain any one selected from among silicon nitride, silicon oxide, and silicon oxynitride.

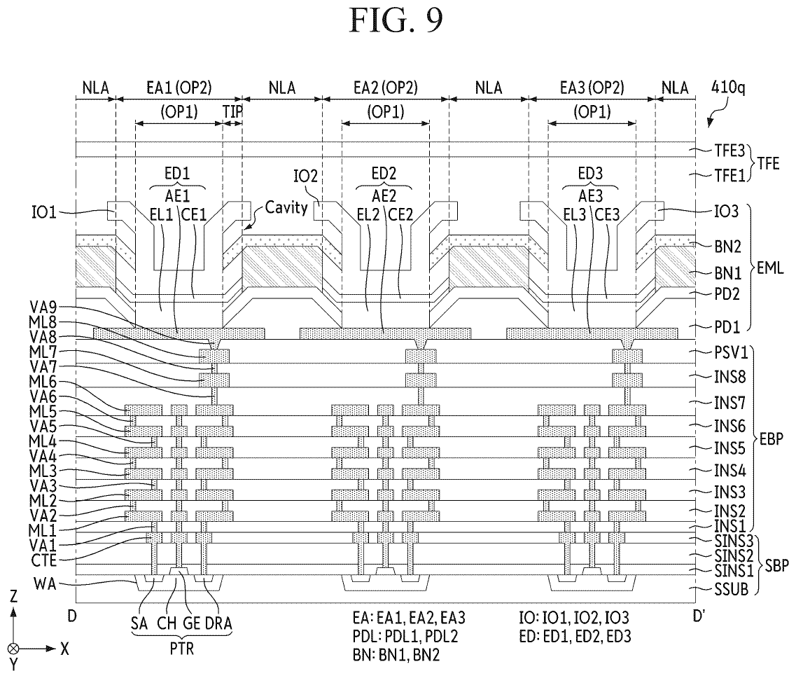

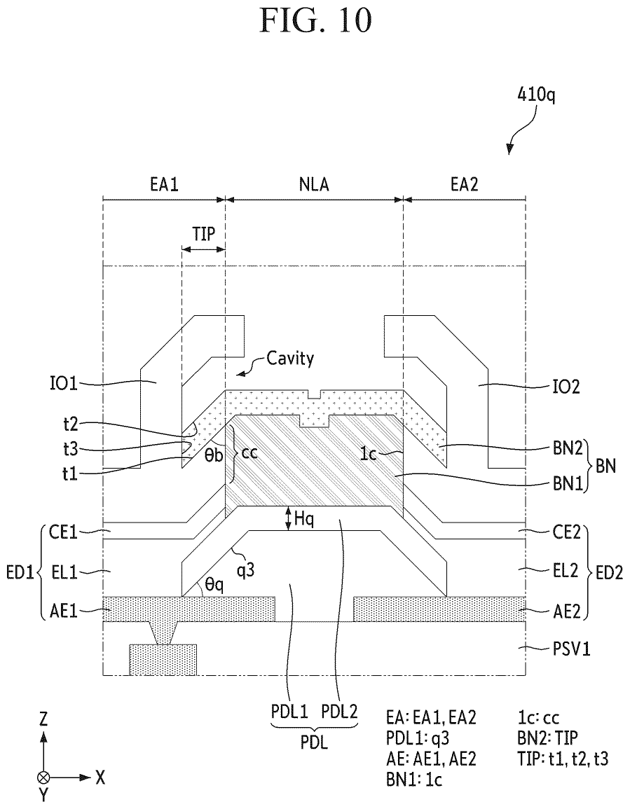

FIG. 9 is a cross-sectional view of a display panel taken along the line D-D′ of FIG. 5 according to one or more embodiments of the present disclosure. FIG. 10 is an enlarged cross-sectional view of a display element layer overlapping a non-emission area located between the first emission area and the second emission area in FIG. 9 according to one or more embodiments. Hereinafter, commonalities between the display panel 410 and a display panel 410q will not be provided, and only differences will be described in more detail later.

Referring to FIG. 9 and FIG. 10, the light emitting element backplane EBP included in the display panel 410q may include the first to eighth metal layers ML1 to ML8, the first to ninth vias VA1 to VA9, the first to eighth interlayer insulating layers INS1 to INS8, and the first passivation layer PSV1.

The first passivation layer PSV1 may entirely cover the eighth interlayer insulating layer INS8. The first passivation layer PSV1 may be located in portions overlapping the emission area EA and the non-emission area NLA. The first passivation layer PSV1 may flatten the lower structure of the display panel 410q. Other redundant descriptions are omitted for conciseness, which may refer to the descriptions FIGS. 6 to 9.

The display element layer EML included in the display panel 410q may be located on the first passivation layer PSV1. The display element layer EML may include the emission area EA and the non-emission area NLA. It may further include the light emitting element ED, the pixel defining layer PDL, and the bank structure BN and the element inorganic layer IO each in a portion overlapping the emission area EA and the non-emission area NLA. The pixel defining layer PDL of the display panel 410q may include a first pixel defining layer PDL1 and a second pixel defining layer PDL2.

The anode electrode AE of the display panel 410q may be located on the first passivation layer PSV1. The anode electrode AE of the display panel 410q may be in overall contact with the first passivation layer PSV1. In a portion overlapping the non-emission area NLA, the first anode electrode AE1, the second anode electrode AE2, and the third anode electrode AE3 may be located to be spaced and/or apart (e.g., spaced apart or separated) from one another on the first passivation layer PSV1. Each of the first anode electrode AE1, the second anode electrode AE2, and the third anode electrode AE3 may be insulated from one another by the first pixel defining layer PDL1.

The first pixel defining layer PDL1 and the second pixel defining layer PDL2 of the display panel 410q may have different shapes and different materials.

The first pixel defining layer PDL1 of the display panel 410q may be located on the anode electrode AE and the first passivation layer PSV1. The first pixel defining layer PDL1 may define the first opening OP1. The first pixel defining layer PDL1 may expose a part of the anode electrode AE in the portion overlapping the first opening OP1. For example, the first pixel defining layer PDL1 may be located to be around (e.g., surround) the first opening OP1.

The first pixel defining layer PDL1 may include a photoreactive organic material. For example, in one or more embodiments, the first pixel defining layer PDL1 may include an acrylic resin, a polyimide, a polyamide, a benzocyclobutene-based resin, a phenol resin, and/or the like.

The first pixel defining layer PDL1 may have a shape protruding in a direction toward the second pixel defining layer PDL2, e.g., toward neighboring emission area. For example, the first pixel defining layer PDL1 may have a convex shape to one side of the third direction (Z-axis direction), i.e., in a direction toward the encapsulation layer TFE. For example, in one or more embodiments, the first pixel defining layer PDL1 may have a trapezoidal shape in which a width of the bottom surface adjacent to (e.g., facing) the anode electrode is greater than a width of the top surface opposite to (e.g., adjacent to or facing) the bank structure.

In one or more embodiments, the first pixel defining layer PDL1 may include a side surface q3. The side surface q3 may be a (e.g., one) surface opposite to (e.g., facing) the emission area EA or may be an inclined surface. For example, the side surface q3 may form a third inclination angle θq with the anode electrode AE. For example, in one or more embodiments, the third inclination angle θq may be in a range of about 20° to about 40°.

The first pixel defining layer PDL1 of the display panel 410q may assist in forming the tip TIP of the second bank layer BN2 to be tilted during the manufacturing process. For example, the first pixel defining layer PDL1 of the display panel 410q may perform the same function as the second passivation layer PSV2 of the display panel 410.

The second pixel defining layer PDL2 of the display panel 410q may be located on the first pixel defining layer PDL1. The second pixel defining layer PDL2 may cover the first pixel defining layer PDL1 with a substantially uniform thickness. Accordingly, the second pixel defining layer PDL2 may have substantially the same profile as the first pixel defining layer PDL1.

The second pixel defining layer PDL2 may include an inorganic insulating material. For example, in one or more embodiments, the pixel defining layer PDL may include any one selected from among aluminum oxide, titanium oxide, tantalum oxide, hafnium oxide, zinc oxide, silicon oxide, silicon nitride, and silicon oxynitride.

In one or more embodiments, a height Hq of the second pixel defining layer PDL2 may be in a range of about 200 nm to about 300 nm.

The bank structure BN of the display panel 410q may be located on the second pixel defining layer PDL2 in a portion overlapping the non-emission area NLA. The bank structure BN may define the second opening OP2.

The first bank layer BN1 of the display panel 410q may be located on the second pixel defining layer PDL2, and the second bank layer BN2 may be located on the first bank layer BN1. The second bank layer BN2 may include the tip TIP that protrudes toward the first opening OP1 beyond the side surface 1c of the first bank layer BN1. Redundant descriptions are omitted, which may refer to the descriptions of FIGS. 6 to 8.

In one or more embodiments, the tip TIP of the second bank layer BN2 may overlap the side surface q3 of the first pixel defining layer PDL1 in the third direction (Z-axis direction).

In one or more embodiments, the first surface t1 and the second surface t2 included in the tip TIP of the second bank layer BN2 may each be an inclined surface that is tilted in the direction parallel to (e.g., substantially parallel to) the side surface q3 of the first pixel defining layer PDL1. Accordingly, the tip TIP of the second bank layer BN2 may have a shape tilted to the other side of the third direction (Z-axis direction) as it goes (e.g., extends) toward the first opening OP1.

In one or more embodiments, the first surface t1 included in the tip TIP of the second bank layer BN2 and the side surface 1c of the first bank layer BN1 may form a second inclination angle θb. For example, in one or more embodiments, the second inclination angle θb may be in a range of about 20°to about 40°. Redundant descriptions are omitted, which may refer to the descriptions of FIGS. 6 to 8.

The bank structure BN of the display panel 410q may cover the first pixel defining layer PDL1 along the shape thereof during the manufacturing process so that it may have the tip TIP tilted in the direction parallel to (e.g., substantially parallel to) the side surface q3 of the first pixel defining layer PDL1. For example, the bank structure BN of the display panel 410q may have the tip TIP that is tilted to the other side of the third direction (Z-axis direction) as it goes (extends) toward the first opening OP1, without utilizing a separate physical process. Accordingly, the display panel 410q may be easily manufactured.

The light emitting layer EL of the display panel 410q may be formed on the anode electrode AE and may be in contact with the side surface 1c of the first bank layer BN1. In one or more embodiments, the light emitting layer EL of the display panel 410q may overlap the emission area EA and completely cover the second pixel defining layer PDL2. In addition, the cathode electrode CE of the display panel 410q may be formed on the light emitting layer EL and may be in contact with the side surface 1c of the first bank layer BN1. Redundant descriptions are omitted, which may refer to the descriptions of FIGS. 6 to 8.

In the display panel 410q, the tip TIP of the second bank layer BN2 has a tilted shape, so that it may assist in preventing or reducing material(s) forming the light emitting layer EL and material(s) forming the cathode electrode CE from being deposited on the upper surface cc of the side surface 1c and the tip TIP. Accordingly, the display panel 410q may solve a reliability defect due to moisture permeation caused by residues of the organic material(s) forming the light emitting layer EL and residues of the conductive material(s) (e.g., metal material(s)) forming the cathode electrode CE.

The element inorganic layer IO of the display panel 410q may overlap the first pixel defining layer PDL1 and the second pixel defining layer PDL2 in the third direction (Z-axis direction). The element inorganic layer IO may be in overall contact with the light emitting element ED to cover it in the portion overlapping the first opening OP1, and may be spaced and/or apart (e.g., spaced apart or separated) from the second bank layer BN2 in the third direction (Z-axis direction) with the cavity (e.g., undercut) interposed therebetween. Other redundant descriptions are omitted, which may refer to the descriptions of FIGS. 6 to 8.

The encapsulation layer TFE of the display panel 410q may overlap the first pixel defining layer PDL1 and the second pixel defining layer PDL2 in the third direction (Z-axis direction). Other redundant descriptions are omitted, which may refer to the descriptions of FIGS. 6 to 8.

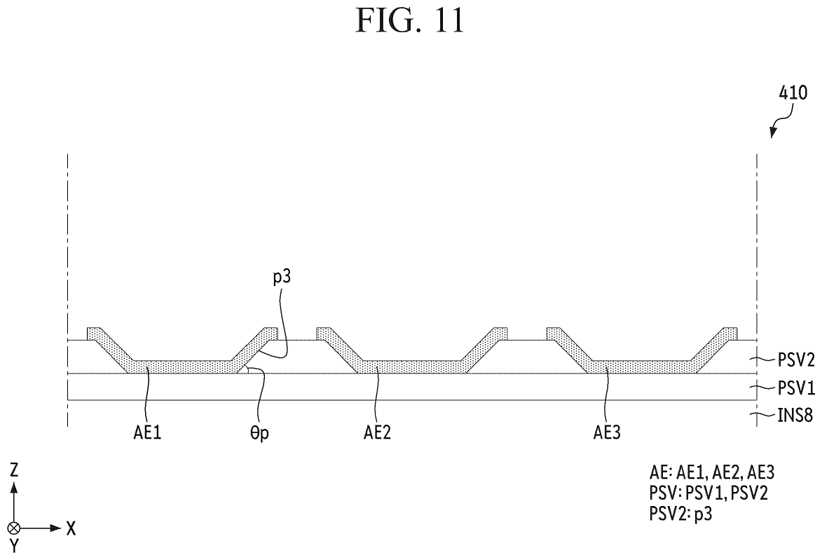

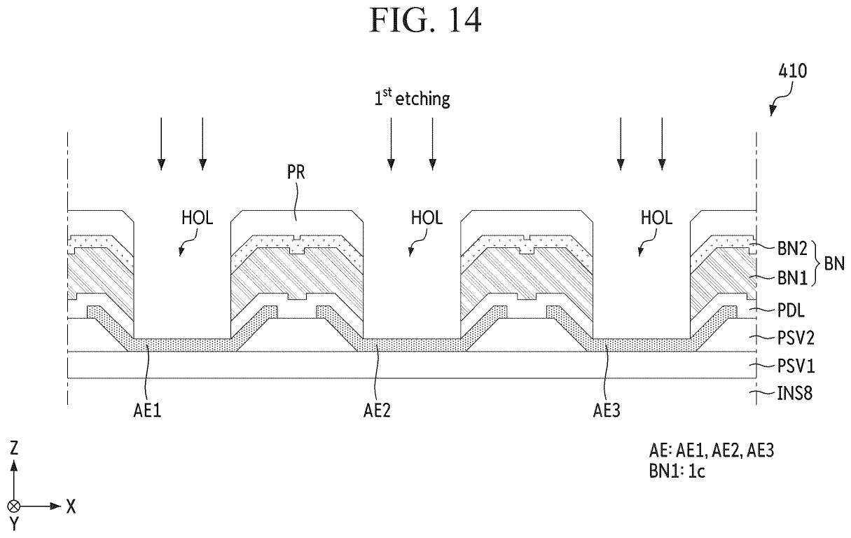

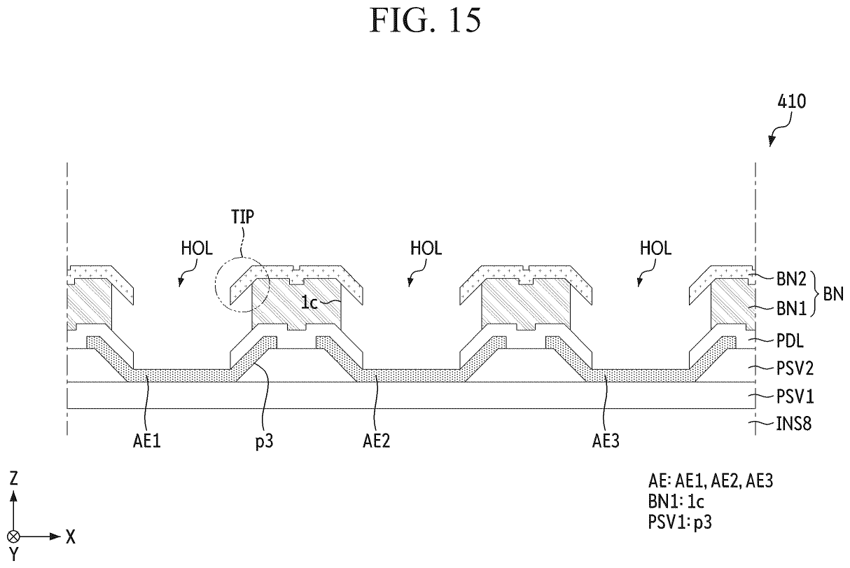

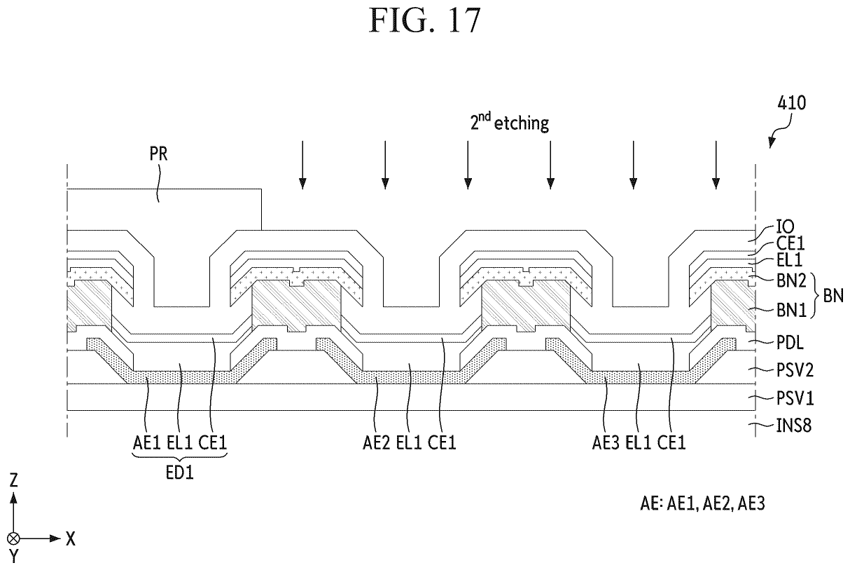

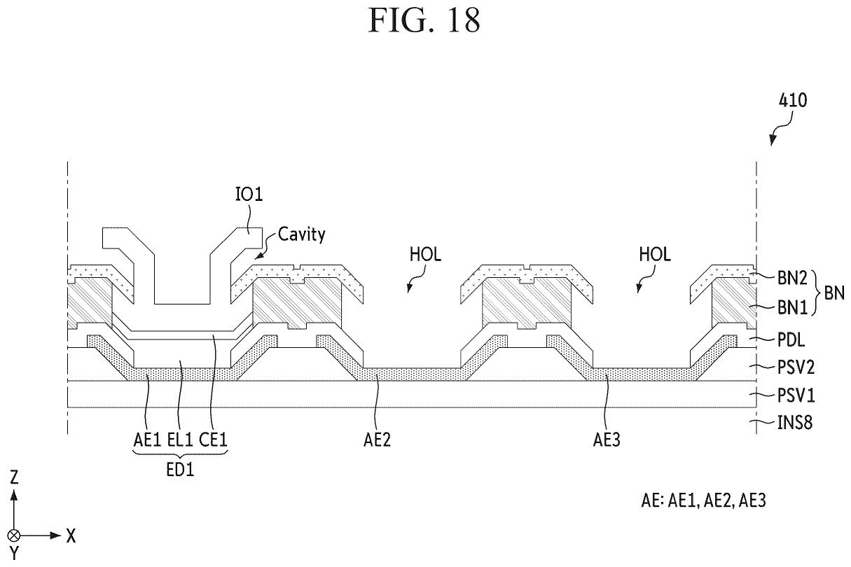

FIGS. 11 to 19 are cross-sectional views schematically illustrating a fabrication method of the display element layer illustrated in FIG. 6 according to one or more embodiments of the present disclosure.

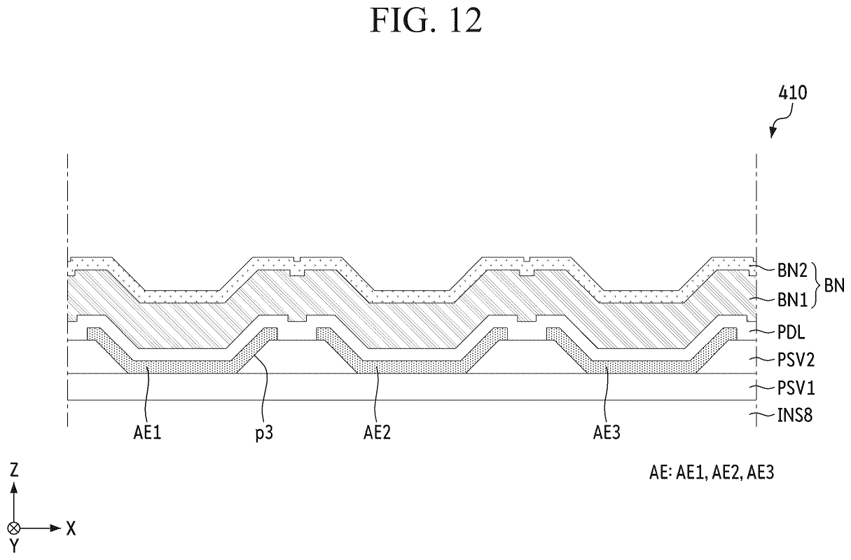

Referring to FIGS. 11 and 12, the first passivation layer PSV1 and the second passivation layer PSV2 are formed on the eighth interlayer insulating layer INS8. It should be noted that for clarity and conciseness, the ninth via VA9 and the eighth metal layer ML8 are omitted in FIGS. 11 to 19. In this process, the first passivation layer PSV1 and the second passivation layer PSV2 may be formed in the same process or in different processes.

For example, in one or more embodiments, if (e.g., when) the first passivation layer PSV1 and the second passivation layer PSV2 are formed in the same process, the passivation layer PSV may be formed using a halftone mask. In these embodiments, the first passivation layer PSV1 and the second passivation layer PSV2 may be formed integrally.

In this process, the second passivation layer PSV2 may be formed to have the inclined side surface p3. For example, in one or more embodiments, the first inclination angle θp formed by the first passivation layer PSV1 and the side surface p3 of the second passivation layer PSV2 may be in a range of about 20° to about 40°. Redundant descriptions are omitted, which may refer to the descriptions of FIGS. 6 to 8.

Next, the plurality of anode electrodes AE are formed on the first passivation layer PSV1. In this process, the plurality of anode electrodes AE may include the first anode electrode AE1, the second anode electrode AE2, and the third anode electrode AE3. The first anode electrode AE1, the second anode electrode AE2 and the third anode electrode AE3 may be spaced and/or apart (e.g., spaced apart or separated) from one another. In this process, each of the first anode electrode AE1, the second anode electrode AE2, and the third anode electrode AE3 may be in contact with the side surface p3 of the second passivation layer PSV2 to cover it.

Next, the pixel defining layer PDL and the bank structure BN are formed entirely on the plurality of anode electrodes AE. In this process, the bank structure BN may include the first bank layer BN1 and the second bank layer BN2 that contain different materials and are sequentially stacked.

In this process, the pixel defining layer PDL, the first bank layer BN1, and the second bank layer BN2 may cover the second passivation layer PSV2 along the shape thereof. Accordingly, the pixel defining layer PDL, the first bank layer BN1, and the second bank layer BN2 may include inclined surfaces in a direction parallel to (e.g., substantially parallel to) the inclined side surface p3 of the second passivation layer PSV2.

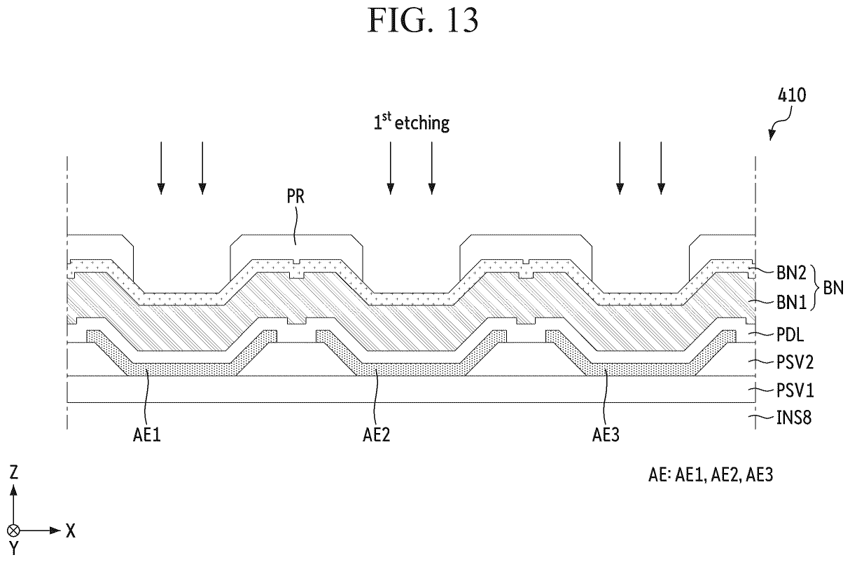

Subsequently, referring to FIGS. 13 to 15, a plurality of photoresists PR are formed on the second bank layer BN2. The plurality of photoresists PR may be spaced and/or apart (e.g., spaced apart or separated) from each other. Subsequently, a first etching process (1^{st} etching) is performed using the plurality of photoresists PR as a mask. For example, in one or more embodiments, the first etching process (1^{st} etching) may be performed by alternately performing a dry etching process and a wet etching process.

For example, first, a dry etching process is performed to isotropically remove parts of the first bank layer BN1, the second bank layer BN2, and the pixel defining layer PDL, which do not overlap the plurality of photoresists PR.

In this process, a hole HOL may be formed in a portion overlapping the anode electrode AE, and the anode electrode AE may be exposed in a portion overlapping the hole HOL. In this process, one surfaces of the first bank layer BN1, the second bank layer BN2, and the pixel defining layer PDL facing the hole HOL may be positioned on the same line, for example, be aligned in the third direction (Z-axis direction). In this process, the hole HOL may be formed in a portion overlapping the emission area EA shown in FIG. 6.

Next, a wet etching process is performed to anisotropically remove parts of the first bank layer BN1 and the second bank layer BN2, which do not overlap the plurality of photoresists PR. In the instant process, the first bank layer BN1 and the second bank layer BN2 including different materials may be different in etching selectivity. For example, an etching rate of the first bank layer BN1 may be higher than an etching rate of the second bank layer BN2 with respect to the same etchant. Accordingly, the second bank layer BN2 may include the tip TIP protruding toward the hole HOL beyond the side surface 1c of the first bank layer BN1.

In this process, the tip TIP of the second bank layer BN2 may have an inclination parallel to (e.g., substantially parallel to) the side surface p3 of the second passivation layer PSV2. For example, the tip TIP of the second bank layer BN2 may be tilted in a direction toward the anode electrode AE (e.g., the other side of the third direction (Z-axis direction)) as it goes toward the hole HOL. For example, the second bank layer BN2 of one or more embodiments may have the tilted tip TIP without utilizing a separate physical process. Accordingly, the display panel 410 may be easily manufactured.

In this process, each of the pixel defining layer PDL and the bank structure BN may have an opening, and the anode electrode AE may be exposed in a portion overlapping each opening. Redundant descriptions are omitted.

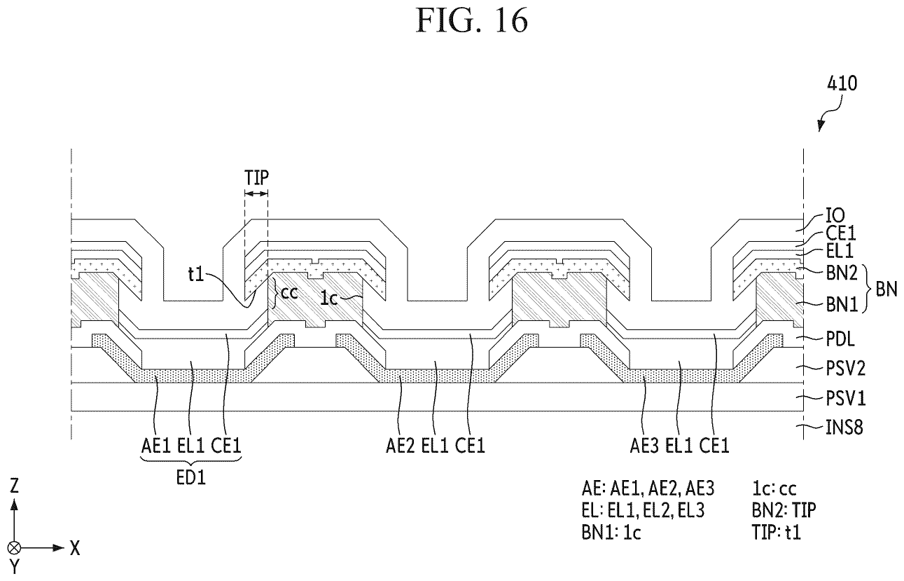

Next, referring to FIGS. 16 to 18, the first light emitting element ED1 is formed by depositing the first light emitting layer EL1, the first cathode electrode CE1, and the element inorganic layer IO on the first anode electrode AE1.

In the instant process, the first light emitting layer EL1 may be formed through a thermal evaporation process. For example, the process of forming the first light emitting layer EL1 may be performed without using a separate fine metal mask. In the instant process, the process of forming the first light emitting layer EL1 may be performed in a state tilted at a first angle from a top surface of the first anode electrode AE. For example, the first angle may be in a range of about 45° to about 50°.

In the display panel 410 of one or more embodiments, the deposition angle of deposition process of forming the light emitting layer EL is performed in a state tilted at the first angle, so that material(s) forming the light emitting layer EL may entirely cover the anode electrode AE and may also be formed on the side surface 1c of the first bank layer BN1.

For example, in this process, if (e.g., when) the material(s) forming the light emitting layer EL is deposited on the first surface t1 of the tip TIP and the upper surface cc of the side surface 1c included in the first bank layer BN1, a moisture and/or oxygen permeation path may be formed with only a small amount of organic residues.

In the display panel 410 of one or more embodiments, as the tip TIP of the second bank layer BN2 has a tilted shape, the material(s) forming the light emitting layer EL may be prevented or reduced from being arranged on the first surface t1 of the tip TIP and the upper surface cc of the side surface 1c during the manufacturing process. Accordingly, the display panel 410 may solve the moisture and/or oxygen permeation defect caused by poor organic material deposition. As described above, in the display panel 410 of one or more embodiments, as the deposition angle of deposition process of forming the light emitting layer EL is performed in a state tilted at the first angle, the material(s) forming the light emitting layer EL may be formed on parts of the anode electrode AE and the side surface 1c of the first bank layer BN1, even though the tip TIP of the second bank layer BN2 is formed to be tilted.

In the present process, the first cathode electrode CE1 may be formed through a thermal evaporation process or a sputtering deposition process. The process of forming the first cathode electrode CE1 may be performed without utilizing a separate fine metal mask and may have a higher step coverage than the deposition process of forming the first light emitting layer EL1.

In the display panel 410 of one or more embodiments, the cathode electrode CE may be formed to entirely cover the light emitting layer EL by performing the deposition process of forming the cathode electrode CE to have a higher step coverage than the process of forming the light emitting layer EL. In addition, the first cathode electrode CE1 may also be formed on the side surface 1c of the first bank layer BN1.

For example, in this process, if (e.g., when) material(s) forming the cathode electrode CE is deposited on the first surface t1 of the tip TIP and the upper surface cc of the side surface 1c included in the first bank layer BN1, a moisture and/or oxygen permeation path may be formed with only a small amount of metal residues.

In the display panel 410 of one or more embodiments, as the tip TIP of the second bank layer BN2 has a tilted shape, the material(s) forming the cathode electrode CE may be prevented or reduced from being arranged on the first surface t1 of the tip TIP and the upper surface cc of the side surface 1c during the manufacturing process. Accordingly, the display panel 410 may solve the moisture and/or oxygen permeation defect caused by poor residue deposition. As described above, in the display panel 410 of one or more embodiments, as the process of forming the cathode electrode CE has a relatively high step coverage, the material(s) forming the cathode electrode CE may be formed on parts of the light emitting layer EL and the side surface 1c of the first bank layer BN1, even though the tip TIP of the second bank layer BN2 is formed to be tilted.

Subsequently, the element inorganic layer IO is formed on the first light emitting element ED1. For example, material(s) forming the element inorganic layer IO is not only formed on the first light emitting element ED1, but may also be arranged on the second anode electrode AE2, the third anode electrode AE3, and the second bank layer BN2.

Subsequently, a photoresist PR is formed on the element inorganic layer IO in a portion overlapping the first light emitting element ED1, and then a second etching process (2^{nd} etching) is performed using the photoresist PR as a mask. For example, the second etching process (2^{nd} etching) may be performed by alternately performing a dry etching process and a wet etching process.

In this process, the material(s) forming the first light emitting layer EL1 that does not overlap the photoresist PR, the material(s) forming the first cathode electrode CE1 that does not overlap the photoresist PR, and the material(s) forming the element inorganic layer IO that does not overlap the photoresist PR may be collectively removed.

In this process, the element inorganic layer IO may be formed in the form of the first element inorganic layer IO1 covering the first light emitting element ED1.

In this process, the first element inorganic layer IO1 and the second bank layer BN2 may be spaced and/or apart (e.g., spaced apart or separated) from each other with a cavity (e.g., an undercut) interposed therebetween, in the third direction (Z-axis direction). The cavity (e.g., undercut) may be formed by removing the material(s) forming the first cathode electrode CE1 and the material(s) forming the first light emitting layer EL1 temporarily located on the second bank layer BN2. The cavity (e.g., undercut) may overlap the tip TIP of the second bank layer BN2 in the third direction (Z-axis direction). Redundant descriptions are omitted.

In this process, the holes HOL may be formed again in portions overlapping the second anode electrode AE2 and the third anode electrode AE3, and the second anode electrode AE2 and the third anode electrode AE3 may be exposed again in portions overlapping the holes HOL.

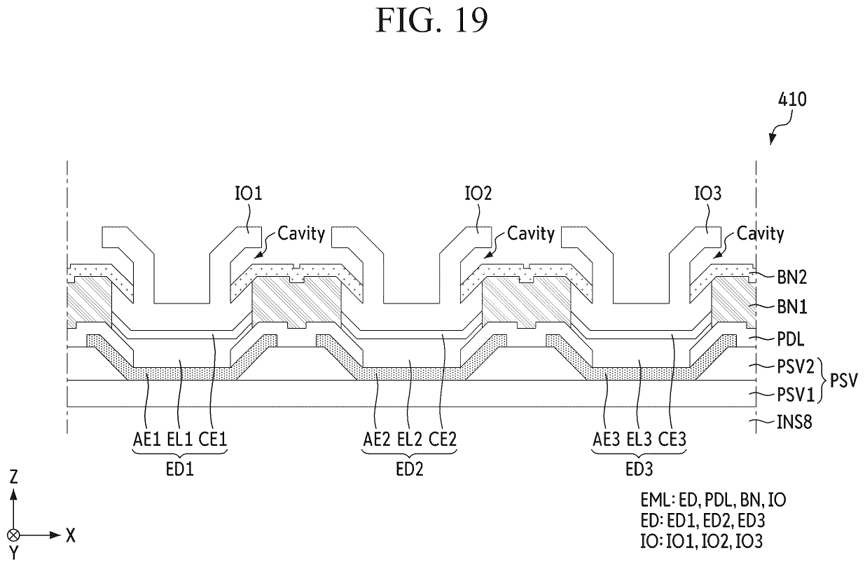

Next, referring to FIG. 19, substantially the same process described above is repeated to form the second light emitting element ED2 and the second element inorganic layer IO2 covering the second light emitting element ED2, and substantially the same process is repeated again to form the third light emitting element ED3 and the third element inorganic layer IO3 covering the third light emitting element ED3.

The first element inorganic layer IO1, the second element inorganic layer IO2, and the third element inorganic layer IO3 may be spaced and/or apart (e.g., spaced apart or separated) from one another in the first direction (X-axis direction). Further, each of the first element inorganic layer IO1, the second element inorganic layer IO2, and the third element inorganic layer IO3 may be spaced and/or apart (e.g., spaced apart or separated) from the second bank layer BN2 with a cavity (e.g., an undercut) interposed therebetween, in the third direction (Z-axis direction). Accordingly, the light emitting element ED, the pixel defining layer PDL, the bank structure BN, and the element inorganic layer IO included in the display element layer EML may be formed.

For example, the cathode electrode CE of the display panel 410 is formed to entirely cover the light-emitting layer EL by using a deposition process with higher step coverage. This process also forms the first cathode electrode CE1 on the side surface of the first bank layer BN1. The tilted shape of the second bank layer BN2 helps prevent or reduce the deposition of cathode electrode material on its tip and side surfaces, addressing moisture and/or oxygen permeation defects caused by poor residue deposition. Subsequently, an element inorganic layer IO is formed on the first light-emitting element ED1 and other components. A photoresist PR is then applied, and a second etching process is performed to remove unwanted materials. This process creates cavities (undercuts) between the first element inorganic layer IO1 and the second bank layer BN2. The same steps (e.g., acts or tasks) are repeated to form additional light-emitting elements and inorganic layers, ensuring they are spaced and/or apart in both the X-axis and Z-axis directions, thus improving the overall structure and performance of the display panel 410 (or, e.g., of the display device).

The display device according to one or more embodiments of the present disclosure can be applied to various electronic devices. The electronic device according to one or more embodiments of the present disclosure includes the display device described above, and may further include modules or devices having additional functions in addition to the display device.

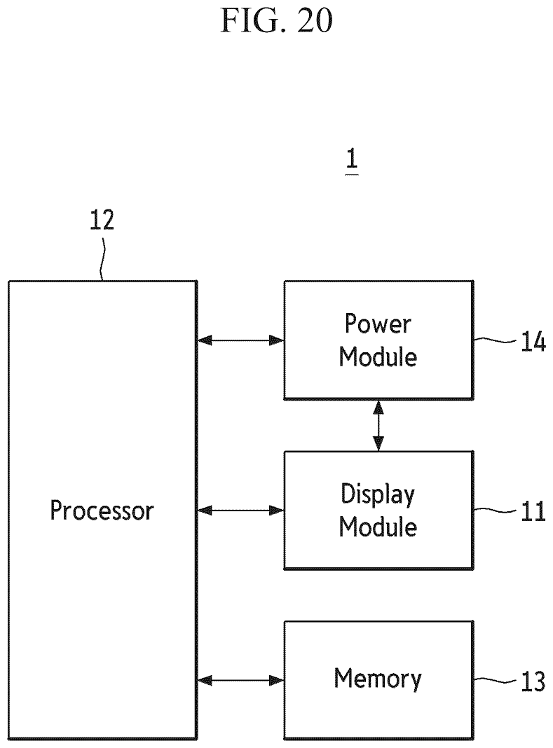

FIG. 20 is a block diagram of an electronic device according to one or more embodiments of the present disclosure.

Referring to FIG. 20, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 1 according to one or more embodiments of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 1 other than the display device 10.

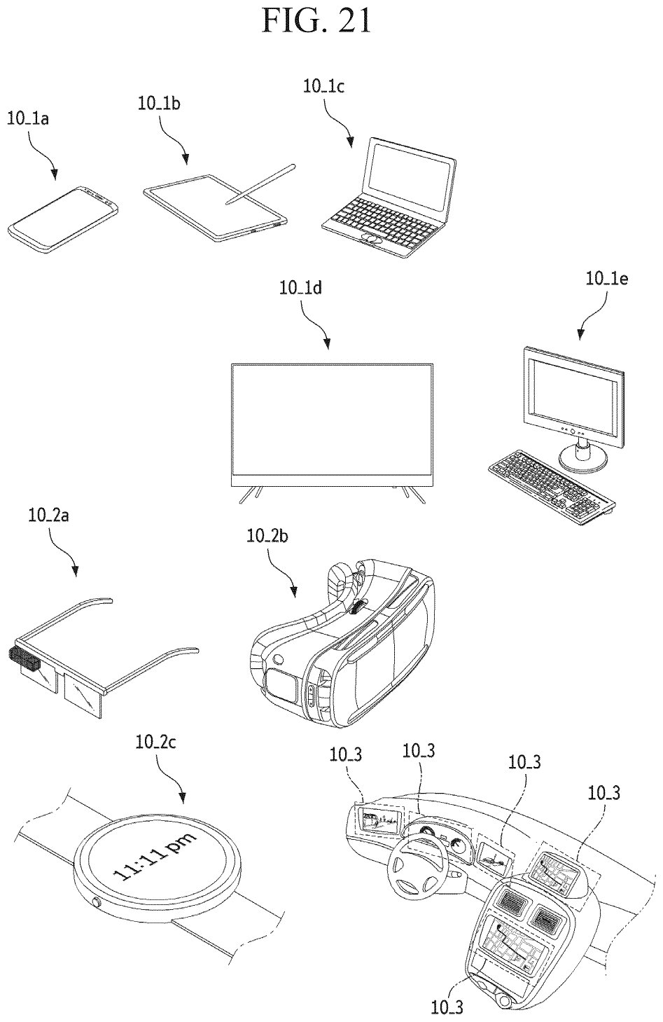

FIG. 21 is a schematic diagram illustrating electronic devices according to various embodiments of the present disclosure.

Referring to FIG. 21, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

Although one or more embodiments of the present disclosure have been described with reference to the accompanying drawings, it will be apparent to those skilled in the art that the present disclosure can be embodied in other specific forms without departing from the technical spirits and essential characteristics. Thus, the above embodiments are to be considered in all respects as illustrative and not restrictive.

In the present disclosure, it will be understood that the terms “comprise(s)/comprising,” “include(s)/including,” or “have/has/having” specify the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms “use,” “using,” and “used” may be considered synonymous with the terms “utilize,”“utilizing,”and “utilized,”respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

The light emitting element, the display panel, the display device, the electronic device/apparatus, the device-manufacturing apparatus (e.g., adhesive member-manufacturing apparatus), or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The embodiments of the present disclosure have been described hereinabove with reference to the accompanying drawings, but it will be understood by one of ordinary skill in the art to which the present disclosure pertains that one or more suitable modifications and alterations may be made without departing from the technical spirit or essential feature of the present disclosure. Therefore, it should be understood that one or more embodiments described above are illustrative in all aspects and not restrictive.

Features of one or more suitable embodiments of the disclosure may be combined partially or totally. As will be clearly appreciated by those skilled in the art, technically one or more suitable interactions and operations are possible. Also, one or more suitable embodiments can be practiced individually or in combination.

In concluding the detailed description, those skilled in the art will appreciate that many variations and modifications can be made to the described embodiments without substantially departing from the principles of present disclosure. Therefore, the disclosed embodiments of present disclosure are used in a generic and descriptive sense and not for purposes of limitation. It is further to be understood that the scope of the present disclosure is defined by the appended claims and equivalents thereof rather than the detailed description described above, and all modifications and alterations derived from the claims and their equivalents fall within the scope of the present disclosure.

What is claimed is:

1. A display device comprising:
a substrate comprising an emission area and a non-emission area;
a passivation layer on the substrate;
a first anode electrode on the passivation layer;
a pixel defining layer on the first anode electrode to overlap the non-emission area, and defining a first opening;
a bank structure on the pixel defining layer and defining a second opening;
a first cathode electrode on the first anode electrode and in contact with the bank structure; and
a first element inorganic layer on the first cathode electrode,
wherein the bank structure comprises a first bank layer and a second bank layer having a tip protruding toward the first opening beyond a side surface of the first bank layer, and
the tip of the second bank layer is tilted toward the substrate as it extends toward the first opening.

2. The display device of claim 1, wherein the passivation layer comprises:
a first passivation layer; and
a second passivation layer on the first passivation layer and overlapping the non-emission area, and
the second passivation layer comprises:
a first surface adjacent to the first passivation layer;
a second surface opposite to the first surface; and
a side surface connecting the first surface and the second surface,
wherein a width of the first surface is greater than a width of the second surface, and
the side surface of the second passivation layer is an inclined surface.

3. The display device of claim 2, wherein the first passivation layer and the side surface of the second passivation layer form a first inclination angle.

4. The display device of claim 3, wherein the first inclination angle is in a range of about 20 degrees to about 40 degrees.

5. The display device of claim 4, wherein the tip of the second bank layer overlaps the side surface of the second passivation layer in a direction normal to the substrate.

6. The display device of claim 4, wherein the tip of the second bank layer is tilted in a direction substantially parallel to the side surface of the second passivation layer.

7. The display device of claim 4, wherein the side surface of the first bank layer and the tip of the second bank layer form a second inclination angle, and
the second inclination angle is in a range of about 20 degrees to about 40 degrees, and
wherein a width of the tip of the second bank layer in a direction parallel to the substrate is in a range of about 500 nanometers to about 1000 nanometers.

8. The display device of claim 2, wherein the first anode electrode is in contact with the side surface of the second passivation layer, and
the display device further comprises:
a second anode electrode spaced from the first anode electrode with the pixel defining layer interposed therebetween; and
a second cathode electrode on the second anode electrode and in contact with the first bank layer, and
wherein the first cathode electrode and the second cathode electrode are electrically connected through the first bank layer.

9. The display device of claim 8, further comprising:
a first light emitting layer on the first anode electrode and in contact with the first bank layer; and
a second light emitting layer on the second anode electrode and in contact with the first bank layer,
wherein the first light emitting layer and the second light emitting layer are spaced from each other with the first bank layer interposed therebetween.

10. The display device of claim 2, further comprising a second element inorganic layer spaced from the first element inorganic layer with the bank structure interposed therebetween,
wherein the first element inorganic layer and the second element inorganic layer are each spaced from the second bank layer with an undercut interposed therebetween in a direction normal to the substrate, and
wherein the undercut overlaps the tip of the second bank layer and the side surface of the second passivation layer in a direction normal to the substrate.

11. The display device of claim 1, wherein the pixel defining layer comprises:
a first pixel defining layer facing the emission area and having an inclined side surface; and
a second pixel defining layer covering the first pixel defining layer with a substantially uniform thickness, and
wherein a side surface of the first pixel defining layer and the first anode electrode forms a third inclination angle.

12. The display device of claim 11, wherein the third inclination angle is in a range of about 20 degrees to about 40 degrees, and
the tip of the second bank layer overlaps the side surface of the first pixel defining layer in a direction normal to the substrate.

13. A method, comprising:
forming a passivation layer on a substrate, and forming an anode electrode on the passivation layer;
forming a pixel defining layer and a bank structure comprising a first bank layer and a second bank layer on the anode electrode;
removing parts of the bank structure and the pixel defining layer to form the second bank layer to have a tip protruding toward a hole overlapping the anode electrode beyond a side surface of the first bank layer; and
forming each of a light emitting layer, a cathode electrode, and an element inorganic layer on the anode electrode,
wherein in the forming of the tip of the second bank layer, the tip of the second bank layer is tilted toward the substrate as it extends toward the hole, and
the method is a method for fabrication of a display device.

14. The method of claim 13, wherein the passivation layer has a side surface forming a first inclination angle with the substrate, and
the tilted tip of the second bank layer is formed to cover the inclined side surface of the passivation layer, and
wherein the tip of the second bank layer overlaps the inclined side surface of the passivation layer in a direction normal to the substrate, and
the first inclination angle is in a range of about 20 degrees to about 40 degrees.

15. The method of claim 14, wherein in the forming of the light emitting layer and the cathode electrode, the light emitting layer and the cathode electrode are each formed through a deposition and etching process without utilizing a separate fine metal mask.

16. An electronic device comprising:
at least one display device comprising a substrate comprising an emission area and a non-emission area;
a display device housing configured to accommodate the at least one display device; and
an optical member configured to magnify a display image of the at least one display device and/or to change an optical path,
wherein the at least one display device comprises:
a passivation layer on the substrate;
an anode electrode on the passivation layer;
a pixel defining layer on the anode electrode to overlap the non-emission area and defining a first opening;
a bank structure on the pixel defining layer and defining a second opening;
a cathode electrode on the anode electrode and in contact with the bank structure; and
an element inorganic layer on the cathode electrode, and
wherein the bank structure comprises a first bank layer and a second bank layer having a tip protruding toward the first opening beyond a side surface of the first bank layer, and
the tip of the second bank layer is tilted toward the substrate as it extends toward the first opening.

17. The electronic device of claim 16, wherein the passivation layer comprises:
a first passivation layer; and
a second passivation layer on the first passivation layer and overlapping the non-emission area, and
the second passivation layer comprises:
a first surface adjacent to the first passivation layer;
a second surface opposite to the first surface; and
a side surface connecting the first surface and the second surface,
wherein a width of the first surface is greater than a width of the second surface, and
the side surface of the second passivation layer is an inclined surface.

18. The electronic device of claim 17, wherein the first passivation layer and the side surface of the second passivation layer form a first inclination angle.

19. The electronic device of claim 18, wherein the first inclination angle is in a range of about 20 degrees to about 40 degrees.

20. The electronic device of claim 19, wherein the tip of the second bank layer overlaps the side surface of the second passivation layer in a direction normal to the substrate.
